(19) United States
(12) Patent Application Publication
(10) Pub. No.: US 2025/0126984 A1
(43) Pub. Date: Apr. 17, 2025

(54) DISPLAY PANEL, PIXEL ARRANGEMENT STRUCTURE AND DISPLAY APPARATUS

(71) Applicants: Hefei Visionox Technology Co., Ltd., Hefei (CN); KunShan Go-Visionox Opto-Electronics Co., Ltd, Kunshan (CN)

(72) Inventors: Yuan YAO, Hefei (CN); Lijun ZHAO, Hefei (CN); Wenyu ZENG, Hefei (CN); Zengqiang XIA, Hefei (CN); Xiaojuan XUE, Hefei (CN); Qianwen WANG, Hefei (CN); Fa-Hsyang CHEN, Hefei (CN)

(73) Assignees: Hefei Visionox Technology Co., Ltd., Hefei (CN); KunShan Go-Visionox Opto-Electronics Co., Ltd, Kunshan (CN)

(21) Appl. No.: 18/952,019

(22) Filed: Nov. 19, 2024

Related U.S. Application Data
(63) Continuation of application No. PCT/CN2024/108359, filed on Jul. 30, 2024.

(30) Foreign Application Priority Data
Oct. 17, 2023 (CN) 202311346196.5

(51) Int. Cl. H10K 59/122; H10K 59/131; H10K 59/80

(52) U.S. Cl. CPC H10K 59/122; H10K 59/131; H10K 59/873

(57) ABSTRACT

A display panel, a pixel arrangement structure, and a display apparatus. The display panel includes: a substrate; an isolation structure, the isolation structure including isolation openings which include a first isolation opening, an orthographic projection pattern of the first isolation opening on the substrate including a first side, an angle between an extension direction of the first side and a first direction being greater than or equal to 0° and less than or equal to 10°; a light-emitting function layer; a first electrode disposed on a side of the light-emitting function layer away from the substrate and connecting with the isolation structure in an overlap manner.

### CROSS-REFERENCE TO RELATED APPLICATIONS

The present application is a continuation application of International Application No. PCT/CN2024/108359, filed on Jul. 30, 2024, which claims priority to Chinese Patent Application No. 202311346196.5, entitled “DISPLAY PANEL, MANUFACTURING METHOD OF DISPLAY PANEL AND DISPLAY APPARATUS” and filed on Oct. 17, 2023, all of which are hereby incorporated by reference in their entireties.

### TECHNICAL FIELD

The present application relates to the technical field of display, and in particular to a display panel, a pixel arrangement structure and a display apparatus.

### BACKGROUND

An organic light emitting diode (OLED) and a flat display apparatus based on a light emitting diode (LED) technology and the like are widely used in various consumer electronic products such as mobile phones, TVs, notebook computers, and desktop computers due to advantages such as high image quality, power saving, a thin body, and a wide range of applications, becoming the mainstream in display apparatuses.

However, operational performance of current OLED display products needs to be improved.

### SUMMARY

Embodiments of the present application provide a display panel, a pixel arrangement structure and a display apparatus, intended to improve operational performance of the display panel.

An embodiment of a first aspect of the present application provides a display panel including a display region, the display panel including: a substrate; an isolation structure disposed on one side of the substrate, the isolation structure including isolation openings which include a first isolation opening, an orthographic projection pattern of the first isolation opening on the substrate including a first side, an angle between an extension direction of the first side and a first direction being greater than or equal to 0° and less than or equal to 10°; a light-emitting function layer at least partially disposed within the isolation openings; a first electrode disposed on a side of the light-emitting function layer away from the substrate and connecting with the isolation structure in an overlap manner; wherein the substrate includes a scan line, the first direction being an extension direction of the scan line in the display region; or the substrate includes a data line, the first direction being an extension direction of the data line in the display region; or the display panel includes a first sub-edge, the first direction being an extension direction of the first sub-edge; or the display panel further includes a non-display region at least partially surrounding the display region, the non-display region including a binding region disposed on a side of the display region in the first direction.

An embodiment of a second aspect of the present application provides a display panel, including: a substrate; an isolation structure disposed on one side of the substrate, the isolation structure including an isolation opening which includes a first isolation opening, and an orthographic projection pattern of the first isolation opening on the substrate including a first side and a second side; a light-emitting function layer at least partially disposed within the isolation opening; a first electrode disposed on a side of the light-emitting function layer away from the substrate, the first electrode including a first subpart and a second subpart, the first subpart of the first electrode being a portion of the first electrode in contact with an inner wall surface of the isolation structure corresponding to the first side, the second subpart of the first electrode being a portion of the first electrode in contact with the inner wall surface of the isolation structure corresponding to the second side, and the inner wall surface of the isolation structure being a surface of the isolation structure facing the isolation opening; wherein in a cross-section along a thickness direction of the display panel, a length of the first subpart of the first electrode in contact with the inner wall surface of the isolation structure is a first overlapping length, a length of the second subpart of the first electrode in contact with the inner wall surface of the isolation structure is a second overlapping length, and the first overlapping length is greater than the second overlapping length.

An embodiment of a third aspect of the present application provides a pixel arrangement structure including a plurality of first pixel groups; wherein the first pixel groups are arranged along a first direction and a second direction respectively, the first direction intersects the second direction, the first pixel group includes: a first sub-pixel disposed within a virtual polygon and including the third side, an angle between an extension direction of the third side and the first direction being greater than or equal to 0° and less than or equal to 10°; a second sub-pixel, the second sub-pixel having a center coinciding with a first vertex of the virtual polygon; and a third sub-pixel, the third sub-pixel having a center coinciding with a second vertex of the virtual polygon adjacent to the first vertex.

An embodiment of a fourth aspect of the present application further provides a display apparatus, including the display panel according to any one of the above embodiments.

An embodiment of the present application provides a display panel including a substrate, an isolation structure, a light-emitting unit, and a first electrode. An orthographic projection pattern of a first isolation opening on the substrate includes a first side. The angle between an extension direction of the first side and a first direction or a second direction perpendicular to the first direction is greater than or equal to 0° and less than or equal to 10°. It has been found by the inventors that when the angle between the extension direction of the first side and the first direction or the second direction is limited to be greater than or equal to 0° and less than or equal to 10°, overlapping effect of the evaporation material of the first electrode within the isolation opening can be improved, thereby reducing the probability of falling off of the light-emitting unit and the first electrode, meanwhile reducing the impedance between the first electrode and the isolation structure, and in turn improving performance of the display panel.

### BRIEF DESCRIPTION OF THE DRAWINGS

In order to more clearly illustrate the technical solutions of the embodiments of the present application, the accompanying drawings to be used in the embodiments of the present application will be briefly introduced below. It will be obvious that the accompanying drawings described hereinafter are only some of the embodiments of the present application, and that for the person of ordinary skill in the art, other accompanying drawings can be obtained based on these accompanying drawings without creative labor.

FIG. 1 is a schematic top structural view of a display panel according to an embodiment of the present application;

FIG. 2 is a schematic diagram of an enlarged structure at Position B in FIG. 1 in an example;

FIG. 3 is a sectional view at C-C in FIG. 2 in an example;

FIG. 4 is a schematic top structural view of another display panel according to an embodiment of the present application;

FIG. 5 is a sectional view at C-C in FIG. 2 in another example;

FIG. 6 is a schematic diagram of an enlarged structure at Position F in FIG. 5 in an example;

FIG. 7 is a sectional view at D-D in FIG. 2 in an example;

FIG. 8 is a schematic diagram of an enlarged structure at Position U in FIG. 7 in an example;

FIG. 9 is a schematic diagram of an enlarged structure at Position B in FIG. 1 in another example;

FIG. 10 is a schematic top structural view of a light-emitting unit in an example;

FIG. 11 is a schematic top structural view of yet another display panel according to an embodiment of the present application;

FIG. 12 is a schematic top structural view of a display panel in a first display region according to an embodiment of the present application;

FIG. 13 is a schematic top structural view of a display panel in a second display region according to an embodiment of the present application;

FIG. 14 is a schematic top structural view of still another display panel according to an embodiment of the present application;

FIG. 15 is a schematic top structural view of a light-emitting unit in another example;

FIG. 16 is a schematic top structural view of a light-emitting unit in yet another example;

FIG. 17 is a schematic top structural view of a light-emitting unit in still another example;

FIG. 18 is a schematic top structural view of a light-emitting unit in still another example;

FIG. 19 is a schematic top structural view of a light-emitting unit in still another example;

FIG. 20 is a schematic top structural view of a light-emitting unit in still another example;

FIG. 21 is a sectional view at O-O in FIG. 12 in an example;

FIG. 22 is a schematic structural view of a pixel arrangement structure according to an embodiment of the present application;

FIG. 23 is a schematic structural view of another pixel arrangement structure according to an embodiment of the present application;

FIG. 24 is a schematic structural view of yet another pixel arrangement structure according to an embodiment of the present application;

FIG. 25 is a schematic structural view of still another pixel arrangement structure according to an embodiment of the present application;

FIG. 26 is a schematic structural view of still another pixel arrangement structure according to an embodiment of the present application;

### DETAILED DESCRIPTION

Features and exemplary embodiments in various aspects of the present application will be described in detail below. In the following detailed description, numerous specific details are set forth in order to provide a thorough understanding of the present application. However, it will be apparent to those skilled in the art that the present application can be implemented without some of these specific details. The following description of the embodiments is merely to provide a better understanding of the present application by illustrating the examples of the present application. In the drawings and the following description, at least part of well-known structures and technologies are not shown in order to avoid unnecessarily obscuring the present application. Further, for clarity, sizes of part of the structures may be exaggerated. Furthermore, the features, structures, or characteristics described below may be combined in any suitable manner in one or more embodiments.

In the description of the present application, it should be noted that, unless otherwise stated, the meaning of “a plurality” is two or more; the orientation or positional relationship indicated by the terms “upper”, “lower”, “left”, “right”, “inner”, “outer”, and the like is merely for the purpose of describing the present application and simplifying the description, and is not intended to indicate or imply that the apparatus or element referred to has a particular orientation, is constructed and operated in a particular orientation, and therefore cannot be understood to be a limitation on the present application. Moreover, the terms “first”, “second”, and the like are for descriptive purposes only and cannot be construed as indicating or implying relative importance.

The terms of orientation in the following description are all directions shown in the drawings and are not intended to limit specific structures of the present application. In the description of the present application, it is to be further noted that unless specifically stated and limited, the terms “mount” and “connect” should be understood in a broad sense, such as, a fixed connection, a detachable connection, or an integral connection; or a direct connection, or an indirect connection. For those of ordinary skill in the art, the specific meanings of the above terms in the present application may be understood depending on specific situations.

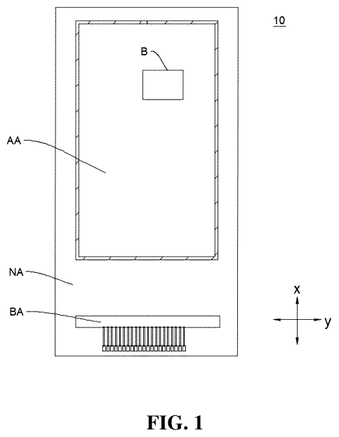

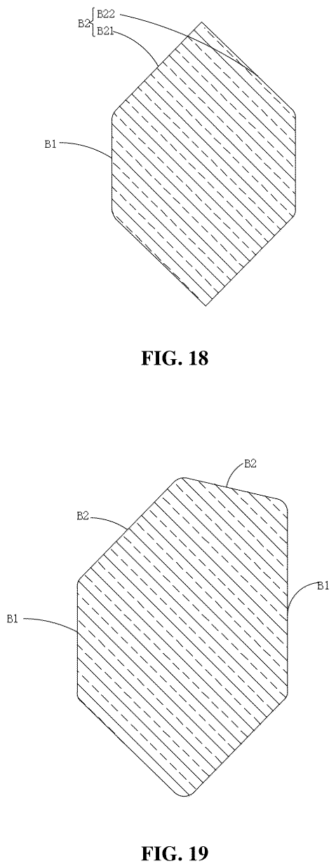

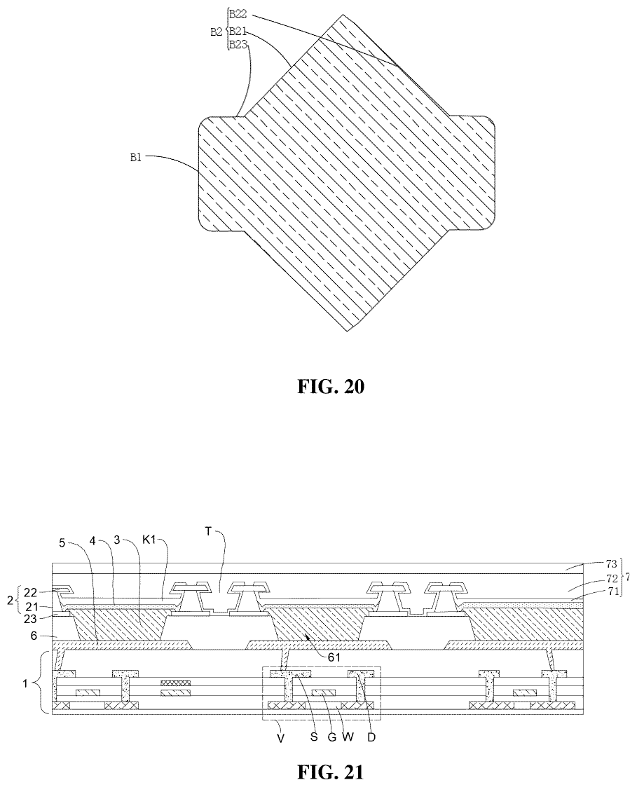

In order to better understand the present application, the display panel, the pixel arrangement structure, and the display apparatus of embodiments of the present application are described in detail below in conjunction with FIGS. 1 to 26 of the accompanying drawings.

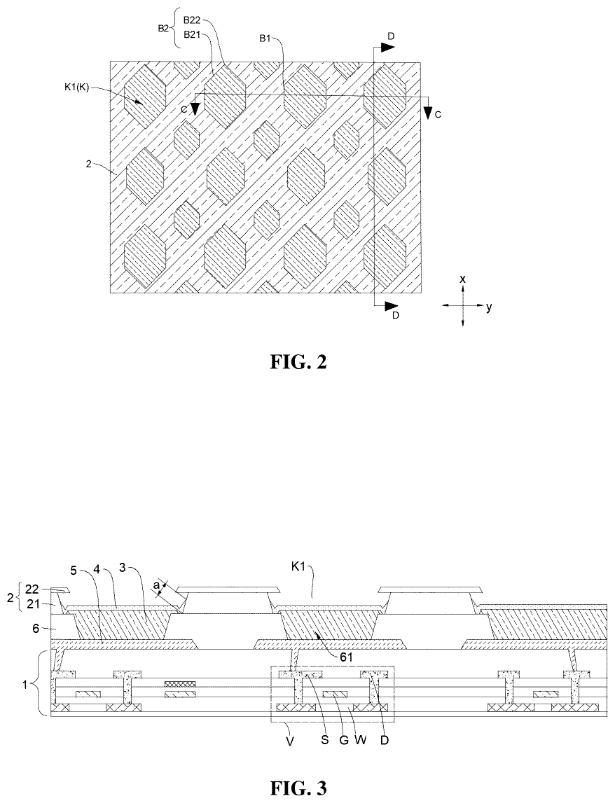

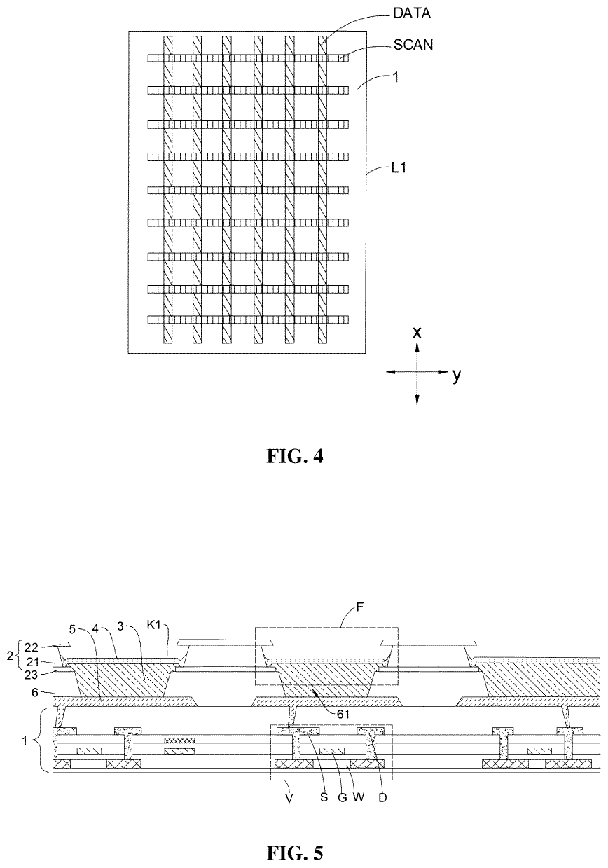

Referring to FIGS. 1 to 4, FIG. 1 is a schematic top structural view of a display panel 10 according to an embodiment of the present application; FIG. 2 is a schematic diagram of an enlarged structure at Position B in FIG. 1 in an example; FIG. 3 is a sectional view at C-C in FIG. 2 in an example; and FIG. 4 is a schematic top structural view of another display panel 10 according to an embodiment of the present application.

As shown in FIGS. 1 to 4, an embodiment of the present application provides a display panel 10 including a display region AA. The display panel 10 includes: a substrate 1; an isolation structure 2 disposed on one side of the substrate 1, the isolation structure including isolation openings K which include a first isolation opening K1, an orthographic projection pattern of the first isolation opening K1 on the substrate 1 including a first side B1, an angle between an extension direction of the first side B1 and a first direction x or a second direction y being greater than or equal to 0° and less than or equal to 10°; a light-emitting function layer 3 at least partially disposed within the isolation openings K; a first electrode 4 disposed on a side of the light-emitting function layer 3 away from the substrate 1 and connecting with the isolation structure 2 in an overlap manner. The substrate 1 includes a scan line SCAN, and the first direction x is an extension direction of the scan line SCAN in the display region AA or the second direction y is the extension direction of the scan line SCAN in the display region AA. Or the substrate 1 includes a data line DATA, and the first direction x is an extension direction of the data line DATA in the display region AA. Or the display panel 10 includes a first sub-edge L1, and the first direction x is an extension direction of the first sub-edge L1. Or the display panel 10 further includes a non-display region NA at least partially surrounding the display region AA. The non-display region NA includes a binding region BA disposed on a side of the display region AA in the first direction x. The first direction x intersects the second direction y. Exemplarily, the first direction x and the second direction y are parallel to the plane where the substrate 1 is located, and the first direction x is perpendicular to the second direction y. Exemplarily, the display panel 10 is in the shape of a polygon, and the first sub-edge L1 of the display panel 10 is a side of the polygon. Exemplarily, the display panel 10 is in the shape of a rectangle, and the first sub-edge L1 is a long side of the rectangle.

The display panel 10 in the embodiments of the present application includes the substrate 1, the isolation structure 2, a light-emitting unit, and the first electrode 4. The orthographic projection pattern of the first isolation opening K1 on the substrate 1 includes the first side B1, and the angle between the extension direction of the first side B1 and the first direction x or the second direction y is greater than or equal to 0° and less than or equal to 10°. It has been found by the inventors that, when the first electrode 4 is evaporated with the evaporation source, if the angle between the extension direction of the first side B1 and the first direction x or the second direction y is limited to be greater than or equal to 0° and less than or equal to 10°, it is possible to improve the overlapping effect of the evaporation material of the first electrode 4 within the isolation openings K, reduce the probability of falling off of the light-emitting function layer 3 and the first electrode 4, and meanwhile reduce the impedance between the first electrode 4 and the isolation structure 2, thereby improving performance of the display panel 10. It is to be noted that if the angle between the side of the isolation opening K and the first direction x or the second direction y is not between 0° and 10°, for example, if the angle between the side of the isolation opening K and the first direction x or the second direction y is greater than 10°, when the first electrode 4 is evaporated with the evaporation source, the overlapping impedance between the first electrode 4 and the isolation structure 2 is too high and exceeds a limit value to guarantee display effect of the product, resulting in a poor overlap.

It is to be noted that the angle between the extension direction of the first side B1 and the first direction x or the second direction y being greater than or equal to 0° and less than or equal to 10° in the present embodiment means that an acute angle formed between the extension direction of the first side B1 and the first direction x or the second direction y is greater than or equal to 0° and less than or equal to 10°.

It is to be noted that in the embodiments herein, the angle between the extension direction of the first side B1 and the first direction x or the second direction y being greater than or equal to 0° and less than or equal to 10° means that: in the same display panel, the angles between extension directions of all the first sides B1 and the first direction x are all greater than or equal to 0° and less than or equal to 10°, and it is a second side B2 the angle between the extension direction of which and the first direction x is not between 0° to 10°; alternatively, in the same display panel, the angles between extension directions of all the first sides B1 and the second direction y are all greater than or equal to 0° and less than or equal to 10°, and it is a second side B2 the angle between the extension direction of which and the second direction y is not between 0° to 10°. In the embodiments herein, the angle between the extension direction of the first side B1 and the first direction x or the second direction y being greater than or equal to 0° and less than or equal to 10° means that when there are a plurality of display panels: the angles between the extension directions of the first sides B1 of all the display panels and the first direction x is greater than or equal to 0° and less than or equal to 10°; or the angles between the extension directions of the first sides B1 of a part of the display panels and the first direction x are greater than or equal to 0° and less than or equal to 10°, and the angles between the extension directions of the first sides B1 of another part of the display panels and the second direction y are greater than or equal to 0° and less than or equal to 10°; or the angles between the extension directions of the first sides B1 of all the display panels and the second direction y is greater than or equal to 0° and less than or equal to 10°. Exemplarily, the first direction x may be a column direction of the display panel or the extension direction of the data line; and the second direction y may be a row direction of the display panel or the extension direction of the scan line.

Patents CN118251982A, 202410864269.8, PCT/CN2024/098407, PCT/CN2024/102783, PCT/CN2024/098217, PCT/CN2024/100935, PCT/CN2024/102785, PCT/CN2024/099419, PCT/CN2024/099072, and CN116685174A have documented relevant technical solutions for an isolation structure and an encapsulation layer, the contents of which are incorporated herein by reference.

Optionally, the first side B1 is a straight-line segment.

Referring to FIG. 4, optionally, the substrate 1 includes a scan line SCAN. The second direction y is an extension direction of the scan line SCAN disposed in the display region AA. The first direction x and the second direction y are perpendicular to each other. The angle between the extension direction of the first side B1 and the first direction x is greater than or equal to 0° and less than or equal to 10°. The first direction x may be an up-down direction, i.e., the column direction, of the display panel 10, and the second direction y may be a left-right direction, i.e., the row direction, of the display panel 10. In another embodiment, the first direction x and the second direction y are interchanged, the substrate 1 includes a scan line SCAN, and the first direction x is the extension direction of the scan line SCAN disposed in the display region AA, i.e., the first direction x may be the left-right direction, i.e., the row direction, of the display panel 10, and the second direction y may be the up-down direction, i.e., the column direction, of the display panel 10.

Referring to FIG. 4, optionally, the substrate 1 includes a data line DATA. The first direction x is parallel to an extension direction of the data line DATA disposed in the display region AA. The data line DATA typically extends along the up-down direction of the display panel 10. The angle between the extension direction of the first side B1 and the first direction x is greater than or equal to 0° and less than or equal to 10°.

Referring to FIG. 4, optionally, the display panel 10 includes a first sub-edge L1, and the first direction x is an extension direction of the first sub-edge L1.

Referring to FIG. 1, optionally, the display panel 10 further includes a non-display region NA that at least partially surrounds the display region AA. The non-display region NA includes a binding region BA disposed on a side of the display region AA in the first direction x. For example, the binding region BA is disposed at a bottom border of the non-display region NA. The first direction x is the up-down direction, i.e., the column direction, of the display panel 10. Correspondingly, the angle between the extension direction of the first side B1 and the first direction x is greater than or equal to 0° and less than or equal to 10°. Alternatively, the angle between the extension direction of the first side B1 and the second direction y is greater than or equal to 0° and less than or equal to 10°, and correspondingly, the angle between the extension direction of the first side B1 and the first direction x is greater than or equal to 80° and less than or equal to 90°.

Optionally, the first side B1 is a straight-line segment or an arc segment. When the first side B1 includes an arc segment, the extension direction of the first side B1 includes the extension directions of tangent segments at different points of the arc segment, i.e., the angle between the extension direction of the tangent segment of the first side B1 at any point and the first direction x or the second direction y is greater than or equal to 0° and less than or equal to 10°.

Optionally, the substrate 1 may include an underlay and an array layer. The array layer may include a driving circuit. For example, the array layer may include a first conductive layer, a second conductive layer, and a third conductive layer disposed on one side of the substrate and stacked. An insulating layer is disposed between any adjacent conductive film layers. Exemplarily, a pixel driving circuit disposed in the array layer includes a transistor V and a storage capacitor. The transistor V includes an active layer W, a gate G, a source S, and a drain D. A material of the source S and the gate G may include a combination of one or more of molybdenum, titanium, aluminum, copper, and the like. The gate G of the transistor is typically used to receive a control signal that causes the transistor to be turned on or off under the control of the control signal. One of the source S and the drain D of the thin film transistor is connected to the light-emitting unit to control the normal light emission of the light-emitting unit.

Optionally, the light-emitting function layer 3 includes one or more of an electron injection layer, an electron transmission layer, a light-emitting material layer, a hole blocking layer, an electron blocking layer, a hole transmission layer, and a hole injection layer. A specific selection may be made according to the specific type of the light-emitting layer, which is not limited specifically.

Optionally, a material of the first electrode 4 may be one of metal materials such as silver (Ag), aluminum (Al), lithium (Li), magnesium (Mg), ytterbium (Yb), calcium (Ca), or indium (In), or an alloy thereof such as magnesium-silver alloy (Mg/Ag), lithium-aluminum alloy (Li/Al), which is not limited in the embodiments.

In some optional embodiments, the first electrode 4 includes a first subpart 41 which is a portion of the first electrode 4 in contact with an inner wall surface of the isolation structure 2 corresponding to the first side B1. The inner wall surface of the isolation structure 2 is a surface of the isolation structure 2 facing the isolation opening K.

It has been found by the inventors' research and experiments that when the angle between the extension direction of the first side B1 and the first direction x or the second direction y is greater than or equal to 0° and less than or equal to 10°, a contact area between the first subpart 41 and the inner wall surface of the isolation structure 2 can be increased, and thus the overlapping effect between the first electrode 4 and the isolation structure 2 can be improved.

Referring to FIG. 3, in some optional embodiments, in a direction away from the substrate 1, the isolation structure 2 includes a first isolation portion 21 and a second isolation portion 22 stacked. An orthographic projection of the first isolation portion 21 on the substrate 1 is within an orthographic projection of the second isolation portion 22 on the substrate 1.

In this embodiment, the isolation structure 2 may include both the first isolation portion 21 and the second isolation portion 22. The orthographic projection of the first isolation portion 21 on the substrate 1 is within the orthographic projection of the second isolation portion 22 on the substrate 1. That is, an orthographic projection area of the first isolation portion 21 on the substrate 1 is less than or equal to an orthographic projection area of the second isolation portion 22 on the substrate 1. For example, when the orthographic projection area of the first isolation portion 21 on the substrate 1 is less than the orthographic projection area of the second isolation portion 22 on the substrate 1, cross-sections of the first isolation portion 21 and the second isolation portion 22 may be in a shape similar to a “T” in a direction perpendicular to the plane where the substrate 1 is located, so as to realize the patterned light-emitting function layer 3 and the first electrode 4 with the isolation structure 2.

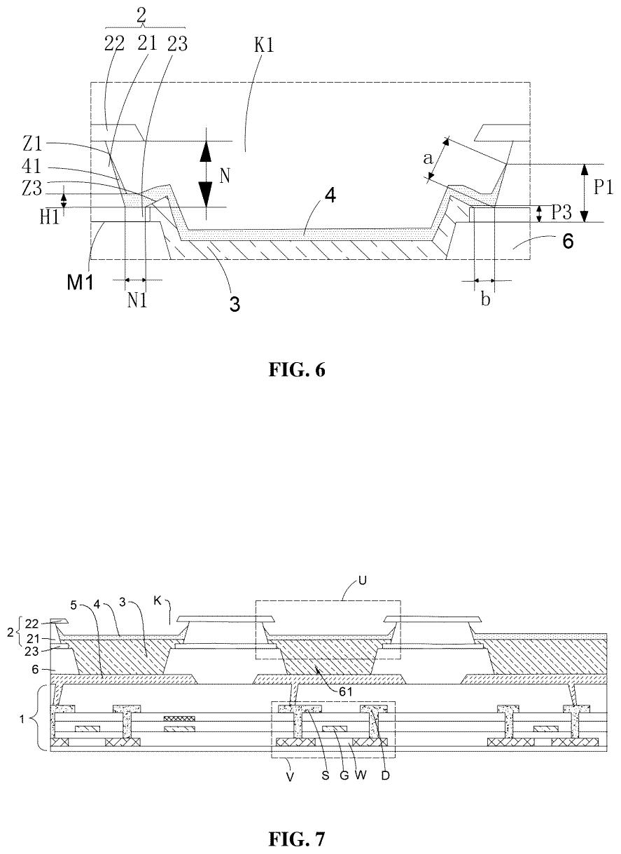

Referring to FIGS. 5 to 6, in some optional embodiments, in a cross-section along a thickness direction of the display panel 10, the first electrode 4 includes a first end portion Z1 which is an edge of the first subpart 41 of the first electrode 4 away from the substrate 1; and the isolation structure 2 includes a first surface M1 proximate to the substrate 1. In the thickness direction of the display panel 10, a distance between the first end portion Z1 of the first electrode 4 and an extension plane of the first surface M1 is a first climb height P1 which is greater than or equal to three-fourths of a height N of the first isolation portion 21.

In this embodiment, a sidewall of the first isolation portion 21 facing the isolation opening K corresponds to an inner wall surface of the isolation structure 2, i.e., the first electrode 4 contacts the first isolation portion 21. The first end portion Z1 is the edge of the first subpart 41 of the first electrode 4 away from the substrate 1, and the first end portion Z1 is the highest point of the first subpart 41 corresponding to the first side B1. In the thickness direction of the display panel 10, the distance between the first end portion Z1 of the first electrode 4 and the extension plane of the first surface M1 is the first climb height P1. The higher the first climb height P1 is, the greater the contact area between the first subpart 41 and the first isolation portion 21 is and the better the overlapping effect is. Thus, in the present embodiments, with the first climb height P1 being greater than or equal to three quarters of the height N of the first isolation portion 21, it is guaranteed that the first subpart 41 and the first isolation portion 21 have a sufficient contact area so as to improve the overlapping effect.

In some optional embodiments, an orthographic projection of an opening surrounded by the second isolation portion 22 on the substrate 1 coincides with an orthographic projection of the corresponding isolation opening K on the substrate 1. That is, the shape and the size of the opening surrounded by the second isolation portion 22 determines the shape and the size of the isolation opening K. A portion of the opening surrounded by the second isolation portion 22 corresponds to the first isolation opening K1. The first side B1 corresponds to an orthographic projection of a portion of a sidewall of the second isolation portion 22 facing the opening surrounded thereby on the substrate 1. That is, the angle between the extension direction of the first side B1 and the first direction x or the second direction y being greater than or equal to 0° and less than or equal to 10° can be realized by adjusting the extension direction of the orthographic projection of the portion of the sidewall of the second isolation portion 22 facing the opening surrounded thereby on the substrate 1.

Referring to FIGS. 5 to 6, in some optional embodiments, the isolation structure 2 further includes a third isolation portion 23 disposed on a side of the first isolation portion 21 away from the second isolation portion 22. The orthographic projection of the first isolation portion 21 on the substrate 1 is within an orthographic projection of the third isolation portion 23 on the substrate 1. The first subpart 41 of the first electrode 4 connects with an inner wall surface of at least one of the first isolation portion 21 and the third isolation portion 23 in an overlap manner.

In this embodiment, the isolation structure 2 includes the first isolation portion 21, the second isolation portion 22, and the third isolation portion 23. The orthographic projection of the first isolation portion 21 on the substrate 1 being within the orthographic projection of the third isolation portion 23 on the substrate 1 means that the orthographic projection area of the first isolation portion 21 on the substrate 1 is less than or equal to an orthographic projection area of the third isolation portion 23 on the substrate 1. For example, in the direction perpendicular to the plane where the substrate 1 is located, the cross-sections of the first isolation portion 21, the second isolation portion 22, and the third isolation portion 23 may be in a shape similar to an “I”, so as to realize a patterned light-emitting function layer 3 using the isolation structure 2. Specifically, during the evaporation of light-emitting material, the light-emitting material may break near the isolation structure 2 to form independent light-emitting units, which can omit a precise mask evaporation process and simplify a manufacturing process of the display panel 10.

It is to be noted that the first subpart 41 of the first electrode 4 connecting with the inner wall surface of at least one of the first isolation portion 21 and the third isolation portion 23 in an overlap manner means that the first subpart 41 of the first electrode 4 may connect with either the first isolation portion 21 or the third isolation portion 23 in an overlap manner, or may connect with both the first isolation portion 21 and the third isolation portion 23 in an overlap manner at the same time. Specifically, since the light-emitting function layer 3 under the first electrode 4 is also formed by the evaporation process, when the light-emitting function layer 3 is only in contact with the third isolation portion 23 and a portion of the third isolation portion 23 is exposed, the first subpart 41 of the first electrode 4 thereon may be in contact with the exposed third isolation portion 23 and may extend to the first isolation portion 21. Alternatively, when the light-emitting function layer 3 is in contact with the third isolation portion 23 and the third isolation portion 23 is not exposed, the first subpart 41 of the first electrode 4 thereon is only in contact with the first isolation portion 21.

Optionally, the first isolation portion 21, the second isolation portion 22, and the third isolation portion 23 all include an electrically conductive material. For example, the first isolation portion 21 includes an aluminum material, the second isolation portion 22 includes a titanium material, and the third isolation portion 23 includes a molybdenum material.

Referring to FIG. 6, in some optional embodiments, the first subpart 41 of the first electrode 4 connects with the first isolation portion 21 and the third isolation portion 23 in an overlap manner. A thickness H1 of the first subpart 41 of the first electrode 4 is greater than or equal to 30 angstroms (Å) at the junction of the first isolation portion 21 and the third isolation portion 23.

It is understood that at the junction of the first isolation portion 21 and the third isolation portion 23, the thickness H1 of the corresponding portion of the first subpart 41 affects the overlapping effect between the first subpart 41 and the first isolation portion 21. The greater the thickness, the better the uniformity of the film layer, so as to ensure that the first electrode 4 has a certain thickness, which prevents fracture due to a nonuniform film layer of the first electrode 4. For example, at the junction of the first isolation portion 21 and the third isolation portion 23, the thickness H1 of the corresponding portion of the first subpart 41 may be equal to any one of 30 Å, 31 Å, 32 Å, 33 Å, 34 Å, 35 Å, with Å being the unit of length.

Referring to FIG. 6, in some optional embodiments, the first subpart 41 of the first electrode 4 connects with the first isolation portion 21 and the third isolation portion 23 in an overlap manner. A distance N1 between an orthographic projection pattern of the light-emitting function layer 3 on the substrate 1 and an orthographic projection edge of the first isolation portion 21 on the substrate 1 corresponding to the first side B1 is greater than or equal to 0.1 μm. The distance N1 may refer to the minimum distance between the orthographic projection pattern of the light-emitting function layer 3 on the substrate 1 and the orthographic projection of the first isolation portion 21 on the substrate 1 corresponding to the first side B1.

It is to be noted that in this embodiment, the light-emitting function layer 3 is only in contact with the third isolation portion 23, and a portion of the third isolation portion 23 is exposed, so that there is a certain distance between the orthographic projection pattern of the light-emitting function layer 3 on the substrate 1 and the orthographic projection of the first isolation portion 21 on the substrate 1 corresponding to the first side B1, which is greater than or equal to 0.1 μm. In this way, the first subpart 41 can be in contact with the exposed portion of the third isolation portion 23. The third isolation portion 23 is manufactured using a molybdenum metal material, and the contact resistance between the first subpart 41 and the third isolation portion 23 is smaller, and the overlapping effect is better.

Referring to FIG. 2, in some optional embodiments, the angle between the extension direction of the first side B1 and the first direction x is greater than or equal to 0° and less than or equal to 10°. The orthographic projection pattern of the first isolation opening K1 on the substrate 1 further includes a second side B2, and the angle between an extension direction of the second side B2 and the first direction x is greater than 10° and less than or equal to 90°. Alternatively, the angle between the extension direction of the first side B1 and the second direction y is greater than or equal to 0° and less than or equal to 10°, the orthographic projection pattern edge of the first isolation opening K1 on the substrate 1 further includes a second side B2, and the angle between the extension direction of the second side B2 and the second direction y is greater than 10° and less than or equal to 90°.

In this embodiment, the second side B2 may form, together with the first side B1, the orthographic projection pattern edge of the first isolation opening K1 on the substrate 1.

In some optional embodiments, a length of the first side B1 is 15% to 45% of a perimeter of the orthographic projection pattern of the isolation opening K on the substrate 1. It is to be understood that, since the disposition of the first side B1 can improve the overlapping effect of the first electrode 4, the greater the proportion of the length of the first side B1 in the perimeter of the orthographic projection pattern of the isolation opening K on the substrate 1, the better the improvement of the overlapping effect of the first electrode 4. It is found by the inventors through research and experiments that, for a cellular phone product, the proportion of the length of the first side B1 in the perimeter of the orthographic projection pattern of the isolation opening K on the substrate 1 being 15% ˜45% can ensure a large opening rate and good display effect of the display panel and improve overlapping effect of the cathode.

Optionally, the proportion of the length of the first side B1 in the perimeter of the orthographic projection pattern of the isolation opening K on the substrate 1 may be any of 15%, 20%, 25%, 30%, 35%, 40%, 45%. For example, the orthographic projection pattern of the isolation opening K on the substrate 1 includes two first sides B1 and two second sides B2, the second sides B2 are semi-circular, the diameter of the second sides B2 is 25 μm, and the length of the first sides B1 is 16.5 μm. Thus the perimeter of the orthographic projection pattern of the isolation opening K on the substrate 1 can be calculated to be about 123.54 μm, and the proportion can be 16.5×2÷123.54=0.27, i.e., 27%. This proportion may correspond to the light-emitting units with a light-emitting color of red. Similarly, the proportion corresponding to the light-emitting units with a light-emitting color of green is 25%, and the proportion corresponding to the light-emitting units with a light-emitting color of blue is 29%. Of course, since different display panels 10 correspond to different isolation openings K of different sizes or shapes, the proportion of the length of the first side B1 in the perimeter of the orthographic projection pattern of the isolation opening K on the substrate 1 is not limited to the above range. For example, for a display panel 10 with a high PPI, such as a VR product, the proportion of the length of the first side B1 in the perimeter of the orthographic projection pattern of the isolation opening K on the substrate 1 may be 60% to 90%.

In some optional embodiments, a total contact area between the first electrode 4 and the inner wall surface of the isolation structure 2 is 15% to 25% of a total area of the inner wall surface of the connected portion of the first electrode 4. For example, the first electrode 4 connects with the first isolation portion 21 of the isolation structure 2 in an overlap manner, and the proportion of the total contact area between the first electrode 4 and the inner wall surface of the isolation structure 2 in the total area of the inner wall surface of the corresponding first isolation portion 21 is 15% to 25%. The inner wall surface of the first isolation portion 21 is a surface of the first isolation portion 21 facing the isolation opening.

It is to be understood that by limiting the angle between the extension direction of the first side B1 and the first direction x or the second direction y to be greater than or equal to 0° and less than or equal to 10°, the contact area between the first electrode 4 and the inner wall surface of the isolation structure 2 can be effectively increased. Thus in this embodiment, the proportion of the total contact area between the first electrode 4 and the inner wall surface of the isolation structure 2 of the display panel 10 in the total area of the inner wall surface of the connected portion of the first electrode 4 is greater, which may be 15% to 25%, for example, any of 15%, 20%, 25%.

It is to be noted that in the case where the first electrode 4 connects with only the first isolation portion 21 of the isolation structure 2 in an overlap manner, the total area of the inner wall surface of the connected portion of the first electrode 4 is the total area of the inner wall surface of the first isolation portion 21 facing the isolation opening K. Exemplarily, the total contact area between the first electrode 4 and the inner wall surfaces of the first isolation portion 21 is 15% to 25% of the total area of the inner wall surface of the first isolation portion 21. Exemplarily, when the first electrode 4 connects with the first isolation portion 21 and the third isolation portion 23 of the isolation structure 2 in an overlap manner, the total area of the inner wall surface of the connected portion of the first electrode 4 is the sum of the total area of the inner wall surface of the first isolation portion 21 facing the isolation opening K and the area of the third isolation portion 23 that is not covered by the light-emitting function layer 3.

In some optional embodiments, the extension direction of the first side B1 is parallel to the first direction x or the second direction y, i.e., the angle between the extension direction of the first side B1 and the first direction x is equal to 0°, or the angle between the extension direction of the first side B1 and the second direction y is equal to 0°, in order to further improve the overlapping effect of the evaporation material of the first electrode 4 inside the isolation opening K and to reduce the possibility of falling off of the light-emitting unit and the first electrode 4, and meanwhile reduce the impedance between the first electrode 4 and the isolation structure 2, thereby improving the performance of the display panel 10.

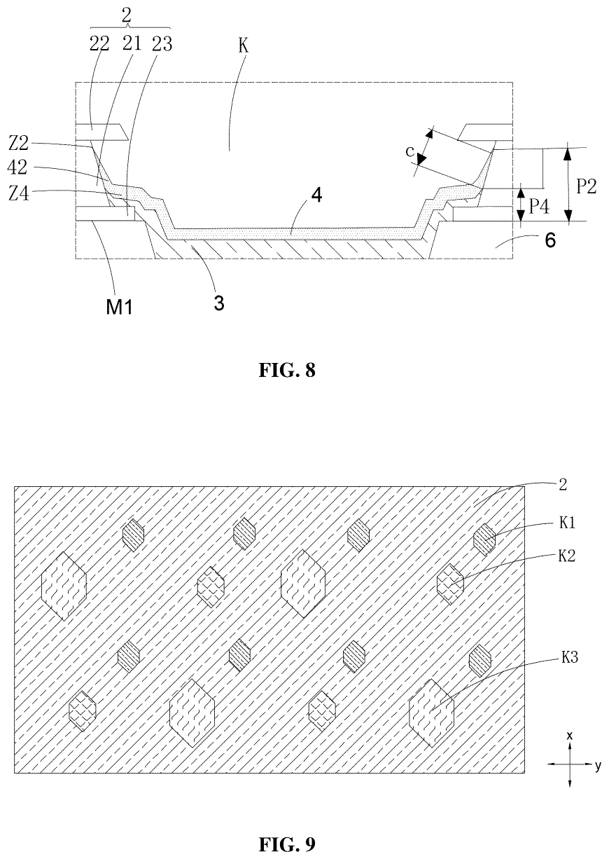

Referring to FIGS. 7 and 8, in some optional embodiments, the first electrode 4 further includes a second subpart 42 which is a portion of the first electrode 4 that is in contact with the inner wall surface of the isolation structure 2 corresponding to the second side B2.

Since the angle between the extension direction of the second side B2 and the first direction x or the second direction y is not in the range of 0° to 10°, the overlapping effect between the first subpart 41 and the inner wall surface of the isolation structure 2 is better than the overlapping effect between the second subpart 42 and the inner wall surface of the isolation structure 2.

Optionally, in the cross-section along the thickness direction of the display panel 10, a length of the first subpart 41 of the first electrode 4 in contact with the inner wall surface of the isolation structure 2 is a first overlapping length, a length of the second subpart 42 of the first electrode 4 in contact with the inner wall surface of the isolation structure 2 is a second overlapping length, and the first overlapping length is greater than the second overlapping length.

It is to be noted that in the cross-section along the thickness direction of the display panel 10, there is may be a first plane and a second plane each perpendicular to the thickness direction of the display panel 10. The first plane is perpendicular to the extension direction of the first side B1. The second plane is perpendicular to the extension direction of the second side B2. The first overlapping length is the length of the first subpart 41 of the first electrode 4 in contact with the inner wall surface of the isolation structure 2 in the first plane. The second overlapping length is the length of the second subpart 42 of the first electrode 4 is in contact with the inner wall surface of the isolation structure 2 in the second plane.

In the case where the first subpart 41 of the first electrode 4 is only in contact with the first isolation portion 21, the first overlapping length is the length at a shown in FIG. 3. In the case where the first subpart 41 of the first electrode 4 is in contact with both the first isolation portion 21 and the third isolation portion 23, the first overlapping length is the sum of a and b shown in FIG. 6.

The same principle is applied to the second overlapping length. For example, as shown in FIG. 8, the second overlapping length is the length at c shown in FIG. 8 when the second subpart 42 of the first electrode 4 is in contact with the first isolation portion 21 only.

The first overlapping length is the length of the first subpart 41 of the first electrode 4 in contact with the inner wall surface of the isolation structure 2 corresponding to the first side B1, and the second overlapping length is the length of the second subpart 42 of the first electrode 4 in contact with the inner wall surface of the isolation structure 2 corresponding to the second side B2. It has been found by the inventors' research that, when the angle between the extension direction of the first side B1 and the first direction x is in the range of 0° to 10° and the angle between the extension direction of the second side B2 and the first direction x is not between 0° and 10°, or when the angle between the extension direction of the first side B1 and the second direction y is between 0° and 10° and the angle between the extension direction of the second side B2 and the second direction y is not between 0° and 10°, the first overlapping length is greater than the second overlapping length, and the overlapping effect between the first subpart 41 and the inner wall surface of the isolation structure 2 is better than the overlapping effect between the second subpart 42 and the inner wall surface of the isolation structure 2.

Optionally, a contact area per unit length of the first subpart 41 of the first electrode 4 in contact with the inner wall surface of the isolation structure 2 is a first area, a contact area per unit length of the second subpart 42 of the first electrode 4 in contact with the inner wall surface of the isolation structure 2 is a second area, and the first area is greater than the second area. The first area is a ratio of a total area of the first subpart 41 of the first electrode 4 in contact with the inner wall surface of the isolation structure 2 to a length of the first side B1, and the second area is a ratio of a total area of the second subpart 42 of the first electrode 4 in contact with the inner wall face of the isolation structure 2 to a length of the second side B2.

It is to be understood that the contact area per unit length is the contact area under the same overlapping length. For example, the unit overlapping length may be 1 μm, depending on the size of the isolation structure 2. Considering that the lengths of the first side B1 and the second side B2 may be different, in the present embodiment, the overlapping effect can be determined accurately by comparing the contact area per unit length of the first subpart 41 of the first electrode 4 in contact with the inner wall surface of the isolation structure 2 and the contact area per unit length of the second subpart 42 of the first electrode 4 in contact with the inner wall surface of the isolation structure 2. The first area is greater than the second area, which indicates that the overlapping effect between the first subpart 41 and the inner wall surface of the isolation structure 2 corresponding to the first side B1 is better. With the limitation of the angle between the extension direction of the first side B1 and the first direction x or the second direction y being greater than or equal to 0° and less than or equal to 10°, the probability of falling off of the light-emitting unit and the first electrode 4 can be reduced, and meanwhile the impedance between the first electrode 4 and the isolation structure 2 can be reduced, which in turn improves the performance of the display panel 10.

Referring to FIGS. 6 and 8, in some optional embodiments, the isolation structure 2 includes a first surface M1 proximate to the substrate 1. The first electrode 4 includes a first end portion Z1 and a second end portion Z2 in a cross-section along a thickness direction of the display panel 10. The first end portion Z1 is an edge of the first subpart 41 of the first electrode 4 away from the substrate 1. The second end portion Z2 is an edge of the second subpart 42 of the first electrode 4 away from the substrate 1. In the thickness direction of the display panel 10, a distance between the first end portion Z1 of the first electrode 4 and an extension plane of the first surface M1 is a first climb height P1, a distance between the second end portion Z2 of the first electrode 4 and an extension plane of the first surface M1 is a second climb height P2, and the first climb height P1 is less than the second climb height P2.

In this embodiment, same as the first end portion Z1, the second end portion Z2 is the edge of the second subpart 42 of the first electrode 4 away from the substrate 1, that is, the second end portion Z2 is the highest point of the second subpart 42 at the corresponding second side B2. It has been found by the inventors that when the angle between the extension direction of the first side B1 and the first direction x is greater than or equal to 0° and is less than or equal to 10°, the first climb height P1 of the first electrode 4 is less than the second climb height P2.

Referring to FIGS. 5 to 8, in some optional embodiments, the light-emitting function layer 3 includes a third end portion Z3 and a fourth end portion Z4 in the cross-section along the thickness direction of the display panel 10. The third end portion Z3 is an edge away from the substrate 1 of a portion of the light-emitting function layer 3 in contact with the inner wall surface of the isolation structure 2 corresponding to the first side B1. The fourth end portion Z4 is an edge away from the substrate 1 of a portion of the light-emitting function layer 3 in contact with the inner wall surface of the isolation structure 2 corresponding to the second side B2. In the thickness direction of the display panel 10, a distance between the third end portion Z3 and the extension plane of the first surface M1 is a third climb height P3, and a distance between the fourth end portion Z4 and the extension plane of the first surface M1 is a fourth climb height P4. The third climb height P3 is less than the fourth climb height P4.

Similar to the first electrode 4, the third end portion Z3 is the edge away from the substrate 1 of a portion of the light-emitting function layer 3 in contact with the inner wall surface of the isolation structure 2 corresponding to the first side B1, i.e., the highest point corresponding to the first side B1 where the light-emitting function layer 3 and the isolation structure 2 come into contact; and the fourth end portion Z4 is the edge away from the substrate 1 of a portion of the light-emitting function layer 3 in contact with the inner wall surface of the isolation structure 2 corresponding to the second side B2, i.e., the highest point corresponding to the second side B2 where the light-emitting function layer 3 and the isolation structure 2 come into contact. The third climb height P3 is less than the fourth climb height P4 due to the evaporation angle.

Optionally, the difference between the first climb height P1 and the third climb height P3 is greater than the difference between the second climb height P2 and the fourth climb height P4, thereby increasing the contact area between the first subpart 41 and the isolation structure 2, and improving the overlapping effect.

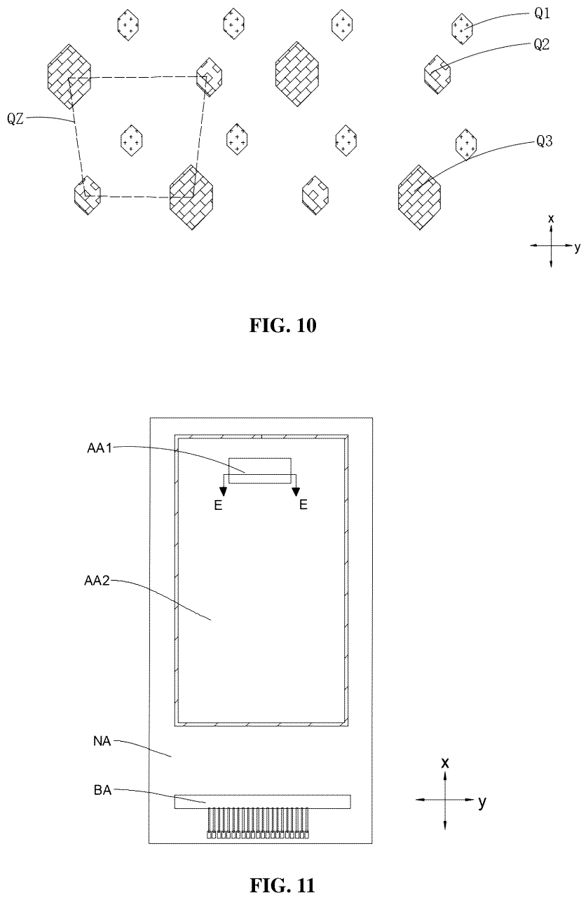

Referring to FIGS. 9 and 10, in some optional embodiments, the light-emitting function layer 3 includes light-emitting units which include a first light-emitting unit Q1, a second light-emitting unit Q2, and a third light-emitting unit Q3. The first light-emitting unit Q1 is disposed to emit light of a first color, the second light-emitting unit Q2 is disposed to emit light of a second color, and the third light-emitting unit Q3 is disposed to emit light of a third color. The isolation opening K further includes a second isolation opening K2 and a third isolation opening K3. At least part of the first light-emitting unit Q1 is disposed within the first isolation opening K1, at least part of the second light-emitting unit Q2 is disposed within the second isolation opening K2, and at least part of the third light-emitting unit Q3 is disposed within the third isolation opening K3.

In this embodiment, orthographic projections of the first isolation opening K1, the second isolation opening K2, and the third isolation opening K3 on the substrate 1 may be of the same shape or may be of different shapes, depending on arrangement form of the first light-emitting unit Q1, the second light-emitting unit Q2, and the third light-emitting unit Q3. Different shapes may be adopted according to the actual demand, thereby increasing application scenarios of the display panel 10.

Optionally, an orthographic projection area of the first isolation opening K1 on the substrate 1 is less than an orthographic projection area of the second isolation opening K2 on the substrate 1, and the orthographic projection area of the first isolation opening K1 on the substrate 1 is less than an orthographic projection area of the third isolation opening K3 on the substrate 1. That is, the orthographic projection area of the first isolation opening K1 on the substrate 1 with the smallest area includes the first side B1, and a light-emitting area of the corresponding first light-emitting unit Q1 emitting the light of the first color is also the smallest. It has been found by the inventors that the smaller the light-emitting area of the light-emitting unit is, the more sensitive it is to the poor overlap. Thus in the embodiments of the present invention, it is at least achieved that the orthographic projection area of the first isolation opening K1 corresponding to the first light-emitting unit Q1 with the smallest light-emitting area on the substrate 1 includes the first side B1, so as to ensure the overlapping effect of the portion of the first electrode 4 corresponding to the first light-emitting unit Q1, thereby improving the display effect.

Optionally, the orthographic projections of the first isolation opening K1, the second isolation opening K2, and the third isolation opening K3 on the substrate 1 all include sides parallel to the first side of the first isolation opening K1 to ensure the overlapping effect of the first light-emitting unit Q1, the second light-emitting unit Q2, and the third light-emitting unit Q3 so as to improve the display effect.

Optionally, the first color, the second color, and the third color are green, red, and blue respectively. Taking into account that the human eye is more sensitive to green, and thus the isolation opening K corresponding to the light-emitting unit with a light-emitting color of green can be disposed in the form of the first isolation opening K1, so as to ensure the overlapping effect of the portion of the first electrode 4 corresponding to the first light-emitting unit Q1 with a light-emitting color of green.

Referring to FIG. 10, in some optional embodiments, the display panel 10 further includes a plurality of light-emitting unit groups QZ. The light-emitting unit groups QZ are arranged along the first direction x and the second direction y. Each light-emitting unit group QZ includes two second light-emitting units Q2, one first light-emitting unit Q1, and two third light-emitting units Q3. The first light-emitting unit Q1 is disposed in the interior of a first virtual quadrilateral. Two opposite vertices of the first virtual quadrilateral coincide with centers of the two second light-emitting units Q2, and the other two opposite vertices coincide with centers of the two third light-emitting units Q3. The first direction x and the second direction y are intersected.

It is to be noted that as described above a center of a light-emitting unit may be defined as a center point of a geometry of the light-emitting unit, i.e., geometric center. A barycenter of a light-emitting unit may be defined as a center point of mass distribution of the geometry of the light-emitting unit, i.e., center of mass. If the geometry of the light-emitting unit is a regular geometry, the geometric center of the light-emitting unit coincides with its barycenter. For example, the light-emitting unit is in the shape of a parallelogram, and intersection of two diagonals of the parallelogram is both the geometric center of the light-emitting unit and its barycenter. If the geometric shape of the light-emitting unit is a non-symmetrical irregular geometric shape, its barycenter can be determined by relevant technology, but its geometric center is more difficult to determine, and at this time, relative position relationship of the geometric center of the light-emitting unit and its barycenter is more difficult to determine.

The light-emitting unit may refer to a structural component in the display panel for light-emitting display.

The first virtual quadrilateral may specifically be a regular shape such as a trapezoid, a rectangle, a rhombus, or in other irregular quadrilateral shapes. A center of an orthographic projection pattern of the first light-emitting unit Q1 on the substrate 1 may coincide with a centroid of the first virtual quadrilateral, or may be misaligned with the centroid of the first virtual quadrilateral by a certain distance.

It is to be noted that the regular pattern in the present invention satisfies at least one of the following cases: 1) a centrosymmetric pattern; 2) an axisymmetric pattern with at least two symmetry axes. For example, an ellipse, a parallelogram (non-rectangular and non-rhombic), a circle, a rounded rectangle, a square polygon, a rectangle, a rhombus, and the like are all regular patterns. For centrosymmetric patterns, the central symmetry point is the center; and for axisymmetric patterns with more than two symmetry axes, intersection of the two symmetry axes is the center. Correspondingly, the patterns rather than the regular patterns are non-regular patterns.

The shape of the first light-emitting unit Q1, the second light-emitting unit Q2, the third light-emitting unit Q3 is not limited to a rectangle, the first light-emitting unit Q1, the second light-emitting unit Q2, the third light-emitting unit Q3 may also be in other regular geometric shapes, such as a circle, a parallelogram, a rhombus, a positive polygons, and so on. The first light-emitting unit Q1, the second light-emitting unit Q2, the third light-emitting unit Q3 shape may also be in non-regular shapes.

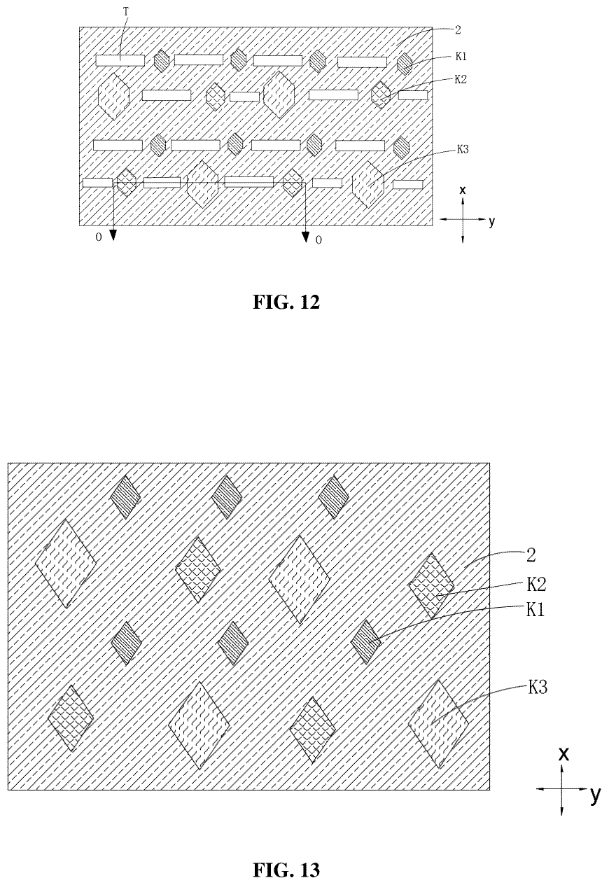

Referring to FIGS. 11 and 12, in some optional embodiments, the display panel 10 includes a first display region AA1 and a second display region AA2 disposed at least on one side of the first display region AA1. Light transmittance of the first display region AA1 is greater than that of the second display region AA2. The first isolation opening K1 is disposed at least in the first display region AA1.

It should be noted that the light transmittance of the first display region AA1 is greater than the light transmittance of the second display region AA2, so that the first display region AA1 may be disposed to install a fingerprint sensor, a face recognition element, etc., with higher light requirements. Since the space of the first display region AA1 is limited, the display effect thereof will also be affected to some extent. Thus, in the present embodiment, the first isolation opening K1 is disposed at least in the first display region AA1, so as to improve the overlapping effect of the evaporation material of the first electrode 4 within the isolation opening K in the first display region AA1, reduce the probability of falling off of the light-emitting unit and the first electrode 4, and at the same time reduce the impedance between the first electrode 4 and the isolation structure 2, which in turn improves the display effect of the display panel 10 in the first display region AA1.

Referring to FIG. 12, in some optional embodiments, in the first display region AA1, the isolation structure 2 further includes a plurality of light-transmitting openings T. The plurality of light-transmitting openings T and the isolation openings K are alternately spaced apart in the second direction y. The first direction x and the second direction y are intersected.

The isolation structure 2 includes a plurality of light-transmitting openings T to improve light transmittance of the display panel 10. The improvement of the light transmittance helps implementation of an under-screen camera solution, as well as improves imaging effect of the under-screen camera. In addition the light-transmitting openings T may also be disposed at a touch trace or a fingerprint trace, thereby reducing overall thickness of the display panel 10.

Optionally, the light-transmitting openings T and the first isolation openings K1 are alternately spaced apart in the second direction y, with the first side B1 facing the adjacent light-transmitting opening T.

With the light-transmitting openings T and the first isolation openings K1 being alternately spaced apart in the second direction y, the orthographic projection pattern of the first isolation opening K1 on the substrate 1 includes the first side B1 parallel to the first direction x, so that there will be no sharp corners protruding out of the side of the first isolation opening K1 facing the light-transmitting opening T to allow the light-transmitting opening T. This, in turn, allows for increase in area and distribution density of the light-transmitting openings T in the display panel 10, further improving the light transmittance of the display panel 10. Moreover, with the first side B1, the overlapping effect between the isolation structure and the cathode can be guaranteed.

Optionally, the projection area of the orthographic projection of the first isolation opening K1 within the first display region AA1 on the substrate 1 is less than the projection area of the orthographic projection of the isolation opening K with the same light-emitting color within the second display region AA2 on the substrate 1. Optionally, the shape of the orthographic projection pattern of the first isolation opening K1 in the first display region AA1 on the substrate 1 is different from that of the first isolation opening K1 in the second display region AA2.

It will be appreciated that since the light-transmitting opening T is additionally disposed in the first display region AA1, which occupies a portion of the space of the first display region AA1, the light-transmitting opening T can be allowed by reducing the area of the first isolation opening K1 within the first display region AA1. In this embodiment, with the orthographic projection pattern of the first isolation opening K1 on the substrate 1 including the first side B1 parallel to the first direction x, the length of the first isolation opening K1 in the second direction y is decreased to leave space for the light-transmitting opening T.

Optionally, within the second display region AA2, a light-emitting unit in the shape of a common diamond or rectangular may be used, as shown in FIG. 13.

Referring to FIGS. 12 and 18, in some optional embodiments, the orthographic projection pattern edge of the first isolation opening K1 within the first display region AA1 on the substrate 1 further includes two second sides B2. The second side B2 within the first display region AA include a first sub-side B21 and a second sub-side B22 connected to each other. Both the first sub-side B21 and the second sub-side B22 are straight-line segments. The first sub-sides B21 of the two second sides B2 are parallel to each other, and the second sub-sides B22 of the two second sides B2 are parallel to each other.

In this embodiment, the second side B2 includes the first sub-side B21 and the second sub-side B22 connected to each other. The first sub-side B21 and the second sub-side B22 are straight-line segments, i.e., the second side B2 is a polyline segment. Lengths of the first sub-side B21 and the second sub-side B22 may be equal to improve the symmetry of the first isolation opening K1.

In the display panel 10 in the embodiments of the present application, the second side B2 includes the first sub-side B21 and the second sub-side B22 connected to each other, the first sub-sides B21 of the two second sides B2 are parallel to each other, and the second sub-sides B22 of the two second sides B2 are parallel to each other, so that the orthographic projection pattern of the first isolation opening K1 on the substrate 1 is in the shape of hexagon with opposite sides being parallel to each other. In this way, a mask plate for manufacturing the first isolation opening K1 need only be simply improved on the basis of the existing mask plate, which in turn saves the design cost of the mask plate. Moreover, by adopting the first isolation opening K1 with the above-described structure and shape, the length of the first isolation opening K1 in the second direction y can be reduced to leave space for the light-transmitting opening T.

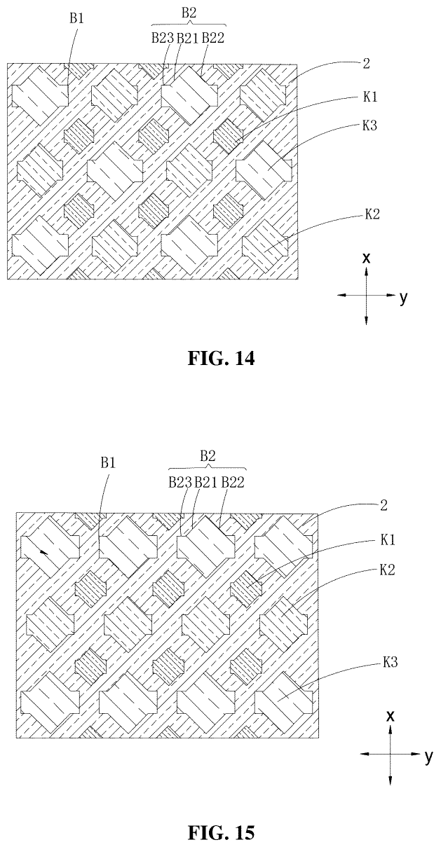

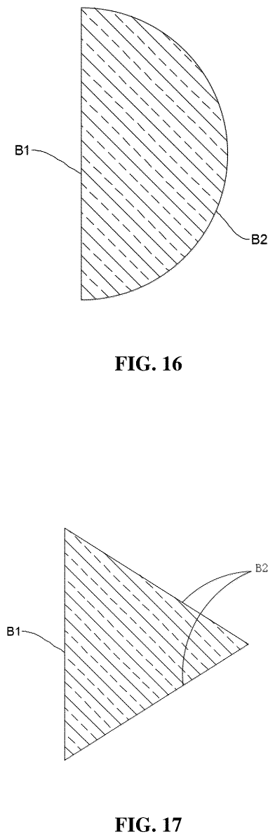

Referring to FIG. 14 or FIG. 15, in some optional embodiments, the orthographic projection pattern edge of the first isolation opening K1 on the substrate 1 includes two first sides B1 and two second sides B2. The second side B2 includes a first sub-side B21 and a second sub-side B22. The first sub-sides B21 and the second sub-sides B22 both are straight-line segments. The first sub-sides B21 of the two second sides B2 are parallel to each other. The second sub-sides B22 of the two second sides B2 are parallel to each other. The second side B2 also includes two third sub-sides B23 which are straight-line segments. The first sub-side B21 and the second sub-side B22 are connected to the two first sides B1 through different third sub-sides B23. The two third sub-sides B23 of the second side B2 are parallel to each other. The third sub-sides B23 of the two second sides B2 are parallel to each other. The first side B1 is convexly formed in a direction away from the isolation opening K.

In the display panel 10 in the embodiments of the present application, with the first side B1 being convexly formed in the direction away from the isolation opening K, the overlapping effect of the evaporation material on the first side B1 is improved as well as the area of the isolation opening K, which in turn improves the opening rate of the display panel 10.

The first isolation opening K1 in this embodiment may be applied to the display panel 10 without the first display region AA1, i.e., the display panel 10 with the same light transmittance in various regions. Or, the first isolation opening K1 in this embodiment may also be applied to the display panel 10 with the first display region AA1 and the second display region AA2. Moreover, the isolation structure 2 with the first side B1 being convexly formed in the direction away from the first isolation opening K1 in the embodiment is disposed in the second display region AA2 to avoid the first side B1 convexly formed from affecting the disposing of the light-transmitting opening T.

Referring to FIGS. 16 to 20, optionally, the first side B1 includes a straight-line segment and the second side B2 includes at least one of a straight-line segment, an arc segment, or a polyline segment. The polyline segment is formed by joining at least two straight-line segments. When the second side B2 includes a polyline segment, the second side B2 includes a plurality of extension directions each of which is the extension direction of the straight-line segment in the polyline segment respectively. When the second side B2 includes an arc segment, the extension directions of the second side B2 include the extension directions of tangent segments at different points of the arc segment.

It is to be noted that in the case where the B2 includes a plurality of extension directions, the angle between the extension direction of B2 and the first direction x being greater than 10° and less than or equal to 90° means that the angles between the plurality of extension directions of B2 and the first direction x are all greater than 10° and less than or equal to 90°.

Referring to FIG. 21, in some optional embodiments, the display panel 10 further includes a pixel-defining layer 6 disposed on a side of the isolation structure 2 proximate to the substrate 1. The pixel-defining layer 6 includes a pixel opening 61. An orthographic projection of the pixel opening 61 on the substrate 1 is within the orthographic projection of the isolation opening K on the substrate 1, and at least part of the light-emitting function layer 3 is disposed in the pixel opening 61.

Optionally, an orthographic projection pattern of the pixel opening 61 on the substrate 1 includes a pixel opening side (not shown) which is parallel or perpendicular to the first direction x. That is, the pixel opening side is parallel or perpendicular to the first side B1.

Optionally, the orthographic projection pattern of the pixel opening 61 on the substrate 1 is of the same shape as the orthographic projection pattern of the isolation opening K on the substrate 1.

Optionally, an edge of the pixel opening 61 coincides with an edge of an effective light-emitting region of the light-emitting unit, i.e. the edge of the pixel opening 61 coincides with an edge of a sub-pixel below.

Optionally, a centroid of the orthographic projection pattern of the pixel opening 61 on the substrate 1 coincides with a centroid of the orthographic projection pattern of the isolation opening K on the substrate 1. That is, the orthographic projection pattern of the pixel opening 61 on the substrate 1 and the orthographic projection pattern of the isolation opening K on the substrate 1 may be similar, and they may be of the same shape, both of which are in the shape such as hexagon but with proportional side lengths, so as to increase luminous output rate.

Specifically, the orthographic projection pattern of the pixel opening 61 on the substrate 1 and the orthographic projection pattern of the isolation opening K on the substrate 1 may be of the same shape. Moreover, an edge of the orthographic projection pattern of the pixel opening 61 on the substrate 1 is conformal with respect to an edge of the orthographic projection pattern of the isolation opening K on the substrate 1, i.e., the edge of the orthographic projection pattern of the pixel opening 61 on the substrate 1 is parallel to the edge of the orthographic projection pattern of the corresponding isolation opening K on the substrate 1, so as to ensure that the light exiting from the pixel opening 61 is not blocked by the isolation structure 2 and to improve luminous efficiency.

As shown in FIG. 21, in some optional embodiments, the display panel 10 further includes an encapsulation layer 7 disposed on a side of the first electrode 4 away from the substrate 1. At least part of the encapsulation layer 7 connects with the isolation structure 2 in an overlap manner.

Optionally, the encapsulation layer 7 includes a first encapsulation layer 71. The first encapsulation layer 71 includes a plurality of first encapsulation units spaced apart from each other. The first encapsulation units are disposed on the side of the first electrode 4 away from the substrate 1. At least part of the first encapsulation units further cover a sidewall of the isolation structure 2 facing the isolation opening K and extend to a side of the isolation structure 2 away from the substrate 1. The first encapsulation units are disposed to encapsulate the isolation opening K, to reduce oxidative erosion of devices within the isolation opening K by external water vapor, thereby prolonging the service life of the display panel 10.

Optionally, a material of the first encapsulation layer 71 includes an inorganic material. That is, the first encapsulation layer 71 is an inorganic encapsulation layer. The inorganic encapsulation layer may be manufactured by chemical vapor deposition, which can improve compactness of the first encapsulation layer 71, thereby improving an encapsulation effect of the encapsulation layer 7.

Optionally, the encapsulation layer 7 further includes a second encapsulation layer 72 disposed on a side of the first encapsulation layer 71 away from the substrate 1. A material of the second encapsulation layer 72 includes an organic material. That is, the second encapsulation layer 72 is an organic encapsulation layer. The organic encapsulation layer may be manufactured by inkjet printing, so that the encapsulation layer 7 has an appropriate thickness.

Optionally, the encapsulation layer 7 further includes a third encapsulation layer 73 disposed on a side of the second encapsulation layer 72 away from the substrate 1. A material of the third encapsulation layer 73 includes an inorganic material. That is, the third encapsulation layer 73 is an inorganic encapsulation layer. Adding an inorganic encapsulation layer outside the organic encapsulation layer can further improve the encapsulation effect of the encapsulation layer 7.

Optionally, the third encapsulation layer 73 and the first encapsulation layer 71 are made of a same material. Therefore, the first encapsulation layer 71 and the third encapsulation layer 73 may be manufactured by a same device, which can simplify the manufacturing process of the display panel 10.

In some optional embodiments, the display panel 10 further includes a second electrode 5 disposed on a side of the light-emitting function layer 3 facing the substrate 1. An orthographic projection of the second electrode 5 on the substrate 1 is at least partially overlapped with the orthographic projection of the isolation opening K on the substrate 1.

A material of the second electrode 5 is generally a material with a high work function in order to improve hole injection efficiency, and may be gold (Au), platinum (Pt), titanium (Ti), silver (Ag), indium tin oxide (ITO), zinc tin oxide (IZO), or a transparent conductive polymer (such as polyaniline). For example, the first electrode 4 layer may be made of an ITO-Ag-ITO composite material without any special limitation.

Referring to FIG. 1 or FIG. 5, another embodiment of the present application provides a display panel including a display region AA and a non-display region NA at least partially surrounding the display region AA. The non-display region NA includes a binding region BA disposed on a side of the display region AA in a first direction x. The display panel includes: a substrate 1; an isolation structure 2, disposed on one side of the substrate 1, with isolation opening K formed by surrounding of at least part of the isolation structure 2, an orthographic projection pattern of the isolation opening K on the substrate 1 including a first side B1 and a second side B2, and the first side B1 being perpendicular or parallel to the first direction x; a light-emitting function layer 3, at least partially disposed within the isolation opening K; and a first electrode 4, disposed on a side of the light-emitting function layer 3 away from the substrate 1 and connecting with the isolation structure 4 in an overlap manner.

The display panel 10 in the embodiment of the present application includes the substrate 1, the isolation structure 2, a light-emitting unit, and the first electrode 4, and the orthographic projection pattern of the isolation opening K on the substrate 1 includes the first side B1 and the second side B2 surrounding the isolation opening K. It has been found by the inventors that, by restricting the first side B1 to be perpendicular or parallel to a first direction x, the overlapping effect of the evaporation material of the first electrode 4 within the isolation opening K can be improved, the probability of falling off of the light-emitting function layer 3 and the first electrode 4 can be reduced, and at the same time the impedance between the first electrode 4 and the isolation structure 2 can be reduced, which in turn improves the performance of the display panel 10.

Referring to FIG. 3 or FIG. 5, another embodiment of the present application provides a display panel 10, including: a substrate 1; an isolation structure 2, disposed on one side of the substrate 1, the isolation structure 2 including an isolation opening K which includes a first isolation opening K1, an orthographic projection pattern edge of the first isolation opening K1 on the substrate 1 including a first side B1 and a second side B2; a light-emitting function layer 3, at least partially disposed within the isolation opening K; a first electrode 4, disposed on a side of the light-emitting function layer 3 away from the substrate 1, the first electrode 4 including a first subpart 41 and a second subpart 42, the first subpart 41 of the first electrode 4 being a portion of the first electrode 4 that is in contact with an inner wall surface of the isolation structure 2 corresponding to the first side B1, the second subpart 42 of the first electrode 4 being a portion of the first electrode 4 that is in contact with the inner wall surface of the second side B2 corresponding to the second side B2, the inner wall surface of the isolation structure 2 being a surface of a side of the isolation structure 2 facing the isolation opening K. In a cross-section along the thickness direction of the display panel 10, a length of the first subpart 41 of the first electrode 4 in contact with the inner wall surface of the isolation structure 2 is a first overlapping length, a length of the second subpart 42 of the first electrode 4 in contact with the inner wall surface of the isolation structure 2 is a second overlapping length, and the first overlapping length is greater than the second overlapping length.

The display panel 10 in the embodiments of the present application includes the substrate 1, the isolation structure 2, a light-emitting unit, and the first electrode 4. The first overlapping length is the length of the first subpart 41 of the first electrode 4 in contact with the inner wall surface of the isolation structure 2 corresponding to the first side B1, and the second overlapping length is the length of the second subpart 42 of the first electrode 4 in contact with the inner wall surface of the isolation structure 2 corresponding to the second side B2. It has been found by the inventors that, in the case where the angle between the extension direction of the first side B1 and the first direction x is between 0° and 10° and the angle between the extension direction of the second side B2 and the first direction x is not between 0° and 10°, or, in the case where the angle between the extension direction of the first side B1 and the second direction y is between 0° and 10° and the angle between the extension direction of the second side B2 and the second direction y is not between 0° and 10°, the first overlapping length is greater than the second overlapping length, so that the overlapping effect between the first subpart 41 and the inner wall surface of the isolation structure 2 is better than the overlapping effect between the second subpart 42 and the inner wall surface of the isolation structure 2, the probability of falling off of the light-emitting unit and the first electrode 4 is reduced, and at the same time the impedance between the first electrode 4 and the isolation structure 2 is reduced, thereby improving the performance of the display panel 10.

Referring to FIG. 3, in some optional embodiments, in the direction away from the substrate 1, the isolation structure 2 includes the first isolation portion 21 and the second isolation portion 22 stacked. The orthographic projection of the first isolation portion 21 on the substrate 1 is within the orthographic projection of the second isolation portion 22 on the substrate 1.

In this embodiment, the isolation structure 2 may include both the first isolation portion 21 and the second isolation portion 22. The orthographic projection of the first isolation portion 21 on the substrate 1 is within the orthographic projection of the second isolation portion 22 on the substrate 1. That is, the orthographic projection area of the first isolation portion 21 on the substrate 1 is less than or equal to the orthographic projection area of the second isolation portion 22 on the substrate 1. For example, when the orthographic projection area of the first isolation portion 21 on the substrate 1 is less than the orthographic projection area of the second isolation portion 22 on the substrate 1, the cross-sections of the first isolation portion 21 and the second isolation portion 22 may be in a shape similar to a “T” in the direction perpendicular to the plane where the substrate 1 is located, so as to realize the patterned light-emitting function layer 3 and the first electrode 4 with the isolation structure 2.

Referring to FIGS. 5 to 6, in some optional embodiments, the isolation structure 2 further includes the third isolation portion 23 disposed on the side of the first isolation portion 21 away from the second isolation portion 22. The orthographic projection of the first isolation portion 21 on the substrate 1 is within the orthographic projection of the third isolation portion 23 on the substrate 1. The first subpart 41 of the first electrode 4 connects with the inner wall surface of at least one of the first isolation portion 21 and the third isolation portion 23 in an overlap manner.

In this embodiment, the isolation structure 2 includes the first isolation portion 21, the second isolation portion 22, and the third isolation portion 23. The orthographic projection of the first isolation portion 21 on the substrate 1 being within the orthographic projection of the third isolation portion 23 on the substrate 1 means that the orthographic projection area of the first isolation portion 21 on the substrate 1 is less than or equal to the orthographic projection area of the third isolation portion 23 on the substrate 1. For example, in the direction perpendicular to the plane where the substrate 1 is located, the cross-sections of the first isolation portion 21, the second isolation portion 22, and the third isolation portion 23 may be in a shape similar to an “I”, so as to realize a patterned light-emitting function layer 3 using the isolation structure 2. Specifically, during the evaporation of light-emitting material, the light-emitting material may break near the isolation structure 2 to form independent light-emitting units, which can omit a precise mask evaporation process and simplify the manufacturing process of the display panel 10.

Referring to FIGS. 5 to 6, in some optional embodiments, in the cross-section along a thickness direction of the display panel 10, the first electrode 4 includes the first end portion Z1 which is the edge of the first subpart 41 of the first electrode 4 away from the substrate 1; and the isolation structure 2 includes the first surface M1 proximate to the substrate 1. In the thickness direction of the display panel 10, the distance between the first end portion Z1 of the first electrode 4 and the extension plane of the first surface M1 is the first climb height P1 which is greater than or equal to three-fourths of the height N of the first isolation portion 21.

In this embodiment, the sidewall of the first isolation portion 21 facing the isolation opening K corresponds to the inner wall surface of the isolation structure 2, i.e., the first electrode 4 contacts the first isolation portion 21. The first end portion Z1 is the edge of the first subpart 41 of the first electrode 4 away from the substrate 1, and the first end portion Z1 is the highest point of the first subpart 41 corresponding to the first side B1. In the thickness direction of the display panel 10, the distance between the first end portion Z1 of the first electrode 4 and the extension plane of the first surface M1 is the first climb height P1. The higher the first climb height P1 is, the greater the contact area between the first subpart 41 and the first isolation portion 21 is and the better the overlapping effect is. Thus, in the present embodiments, with the first climb height P1 being greater than or equal to three quarters of the height N of the first isolation portion 21, it is guaranteed that the first subpart 41 and the first isolation portion 21 have a sufficient contact area so as to improve the overlapping effect.

In some optional embodiments, the orthographic projection of the opening surrounded by the second isolation portion 22 on the substrate 1 coincides with the orthographic projection of the corresponding isolation opening K on the substrate 1. That is, the shape and the size of the opening surrounded by the second isolation portion 22 determines the shape and the size of the isolation opening K. A portion of the opening surrounded by the second isolation portion 22 corresponds to the first isolation opening K1. The first side B1 corresponds to the orthographic projection of the portion of the sidewall of the second isolation portion 22 facing the opening surrounded thereby on the substrate 1. That is, the angle between the extension direction of the first side B1 and the first direction x or the second direction y being greater than or equal to 0° and less than or equal to 10° can be realized by adjusting the extension direction of the orthographic projection of the portion of the sidewall of the second isolation portion 22 facing the opening surrounded thereby on the substrate 1.

Referring to FIGS. 5 to 6, in some optional embodiments, the first subpart 41 of the first electrode 4 connects with the first isolation portion 21 and the third isolation portion 23 in an overlap manner. The thickness H1 of the first subpart 41 is greater than or equal to 30 Å at the junction of the first isolation portion 21 and the third isolation portion 23.

It is understood that at the junction of the first isolation portion 21 and the third isolation portion 23, the thickness H1 of the corresponding portion of the first subpart 41 affects the overlapping height between the first subpart 41 and the first isolation portion 21. The greater the thickness, the greater the overlapping height, the greater the contact area between the first subpart 41 and the first isolation portion 21, and the better the overlapping effect. For example, at the junction of the first isolation portion 21 and the third isolation portion 23, the thickness H1 of the corresponding portion of the first subpart 41 may be equal to any one of 30 Å, 31 Å, 32 Å, 33 Å, 34 Å, 35 Å, with Å being the unit of length.

Referring to FIGS. 5 to 6, in some optional embodiments, the first subpart 41 of the first electrode 4 connects with the first isolation portion 21 and the third isolation portion 23 in an overlap manner. The distance N1 between an orthographic projection pattern edge of the light-emitting function layer 3 on the substrate 1 and the orthographic projection edge of the first isolation portion 21 on the substrate 1 corresponding to the first side B1 is greater than or equal to 0.1 μm.

It is to be noted that in this embodiment, the light-emitting function layer 3 is only in contact with the third isolation portion 23, and a portion of the third isolation portion 23 is exposed, so that there is a certain distance between the orthographic projection pattern of the light-emitting function layer 3 on the substrate 1 and the orthographic projection of the first isolation portion 21 on the substrate 1 corresponding to the first side B1, which is greater than or equal to 0.1 μm. In this way, the first subpart 41 can be in contact with the exposed portion of the third isolation portion 23. The third isolation portion 23 is manufactured using a molybdenum metal material, and conductive effect between the first subpart 41 and the third isolation portion 23 is better.

Referring to FIGS. 1 and 4, in some optional embodiments, the angle between the extension direction of the first side B1 and the first direction x is between 0° and 10°, and the angle between the extension direction of the second side B2 and the first direction x is not between 0° and 10°. Alternatively, the angle between the extension direction of the first side B1 and the second direction y is between 0° and 10°, and the angle between the extension direction of the second side B2 and the second direction y is not between 0° and 10°. The substrate 1 includes the scan line SCAN, and the second direction y is the extension direction of the scan line SCAN in the display region AA. Or the substrate 1 includes the data line DATA, and the first direction x is the extension direction of the data line DATA in the display region AA. Or the display panel 10 includes the first sub-edge L1, and the first direction x is the extension direction of the first sub-edge L1. Or the display panel 10 further includes a non-display region NA at least partially surrounding the display region AA. The non-display region NA includes a binding region BA disposed on a side of the display region AA in the first direction x. Optionally, the first direction x and the second direction y are parallel to the plane where the substrate 1 is located, and the first direction x is perpendicular to the second direction y. Exemplarily, the display panel 10 is in the shape of a polygon, and the first sub-edge L1 of the display panel 10 is a side of the polygon. Exemplarily, the display panel 10 is in the shape of a rectangle, and the first sub-edge L1 is a long side of the rectangle. In another embodiment, the first direction x and the second direction y are interchanged. The substrate 1 includes the scan line SCAN, and the first direction x is the extension direction of the scan line SCAN disposed in the display region AA, i.e., the first direction x may be the left-right direction, i.e., the row direction, of the display panel 10, and the second direction y may be the up-down direction, i.e., the column direction, of the display panel 10.

Optionally, the substrate 1 includes the scan line SCAN, and the second direction y is the extension direction of the scan line SCAN in the display region AA. The first direction x and the second direction y are perpendicular to each other, and the angle between the extension direction of the first side B1 and the first direction x is greater than or equal to 0° and less than or equal to 10°, the first direction x may be the up-down direction, i.e., the column direction, of the display panel 10, and the second direction y may be the left-right direction, i.e., the row direction, of the display panel 10.

Optionally, the substrate 1 includes the data line DATA, and the first direction x is the extension direction of the data line DATA in the display region AA. The data line DATA typically extends along the up-down direction of the display panel 10, and the angle between the extension direction of the first side B1 and the first direction x is greater than or equal to 0° and less than or equal to 10°.

Optionally, the display panel 10 includes the first sub-edge L1, and the first direction x is the extension direction of the first sub-edge L1.

Optionally, the display panel 10 further includes the non-display region NA that at least partially surrounds the display region AA. The non-display region NA includes the binding region BA disposed on a side of the display region AA in the first direction x. For example, the binding region BA is disposed at the bottom border of the non-display region NA. The first direction x is the up-down direction, i.e., the column direction, of the display panel 10. The angle between the extension direction of the first side B1 and the first direction x is greater than or equal to 0° and less than or equal to 10°. Alternatively, the angle between the extension direction of the second side B2 and the first direction x is greater than or equal to 0° and less than or equal to 10°.

Optionally, the contact area per unit length of the first subpart 41 of the first electrode 4 in contact with the inner wall surface of the isolation structure 2 is the first area, the contact area per unit length of the second subpart 42 of the first electrode 4 in contact with the inner wall surface of the isolation structure 2 is the second area, and the first area is greater than the second area. The first area is the ratio of the total area of the first subpart 41 of the first electrode 4 in contact with the inner wall surface of the isolation structure 2 to the length of the first side B1, and the second area is the ratio of the total area of the second subpart 42 of the first electrode 4 in contact with the inner wall face of the isolation structure 2 to the second overlapping length.

It is to be understood that the contact area per unit length is the contact area under the same overlapping length. For example, the unit overlapping length may be 1 μm, depending on the size of the isolation structure 2. Considering that the lengths of the first side B1 and the second side B2 may be different, in the present embodiment, the overlapping effect can be determined accurately by comparing the contact area per unit length of the first subpart 41 of the first electrode 4 in contact with the inner wall surface of the isolation structure 2 and the contact area per unit length of the second subpart 42 of the first electrode 4 in contact with the inner wall surface of the isolation structure 2. The first area is greater than the second area, which indicates that the overlapping effect between the first subpart 41 and the inner wall surface of the isolation structure 2 corresponding to the first side B1 is better. With the limitation of the angle between the extension direction of the first side B1 and the first direction x or the second direction y being greater than or equal to 0° and less than or equal to 10°, the probability of falling off of the light-emitting unit and the first electrode 4 can be reduced, and meanwhile the impedance between the first electrode 4 and the isolation structure 2 can be reduced, which in turn improves the performance of the display panel 10.

Referring to FIGS. 5 to 8, in some optional embodiments, the isolation structure 2 includes the first surface M1 proximate to the substrate 1. The first electrode 4 includes the first end portion Z1 and the second end portion Z2 in the cross-section along the thickness direction of the display panel 10. The first end portion Z1 is the edge of the first subpart 41 of the first electrode 4 away from the substrate 1. The second end portion Z2 is the edge of the second subpart 42 of the first electrode 4 away from the substrate 1. In the thickness direction of the display panel 10, the distance between the first end portion Z1 of the first electrode 4 and the extension plane of the first surface M1 is the first climb height P1, the distance between the second end portion Z2 of the first electrode 4 and the extension plane of the first surface M1 is the second climb height P2, and the first climb height P1 is less than the second climb height P2.

In this embodiment, same as the first end portion Z1, the second end portion Z2 is the edge of the second subpart 42 of the first electrode 4 away from the substrate 1, i.e., the second end portion Z2 is the highest point of the second subpart 42 at the corresponding second side B2. It has been found by the inventor's research that, when the first electrode is evaporated with the evaporation source, the angle between the extension direction of the first side B1 and the first direction x is greater than or equal to 0° and less than or equal to 10°, and correspondingly the first climb height P1 of the first electrode 4 is less than the second climb height P2.

In some optional embodiments, the light-emitting function layer 3 includes the third end portion Z3 and the fourth end portion Z4 in the cross-section along the thickness direction of the display panel 10. The third end portion Z3 is the edge away from the substrate 1 of the portion of the light-emitting function layer 3 in contact with the inner wall surface of the isolation structure 2 corresponding to the first side B1. The fourth end portion Z4 is the edge away from the substrate 1 of the portion of the light-emitting function layer 3 in contact with the inner wall surface of the isolation structure 2 corresponding to the second side B2. In the thickness direction of the display panel 10, the distance between the third end portion Z3 and the extension plane of the first surface M1 is the third climb height P3, and the distance between the fourth end portion Z4 and the extension plane of the first surface M1 is the fourth climb height P4. The third climb height P3 is less than the fourth climb height P4.

Similar to the first electrode 4, the third end portion Z3 is the edge away from the substrate 1 of the portion of the light-emitting function layer 3 in contact with the inner wall surface of the isolation structure 2 corresponding to the first side B1, i.e., the highest point corresponding to the first side B1 where the light-emitting function layer 3 and the isolation structure 2 come into contact; and the fourth end portion Z4 is the edge away from the substrate 1 of the portion of the light-emitting function layer 3 in contact with the inner wall surface of the isolation structure 2 corresponding to the second side B2, i.e., the highest point corresponding to the second side B2 where the light-emitting function layer 3 and the isolation structure 2 come into contact. The third climb height P3 is less than the fourth climb height P4 due to the evaporation angle.

Optionally, the difference between the first climb height P1 and the third climb height P3 is greater than the difference between the second climb height P2 and the fourth climb height P4, thereby increasing the contact area between the first subpart 41 and the isolation structure 2, and improving the overlapping effect.

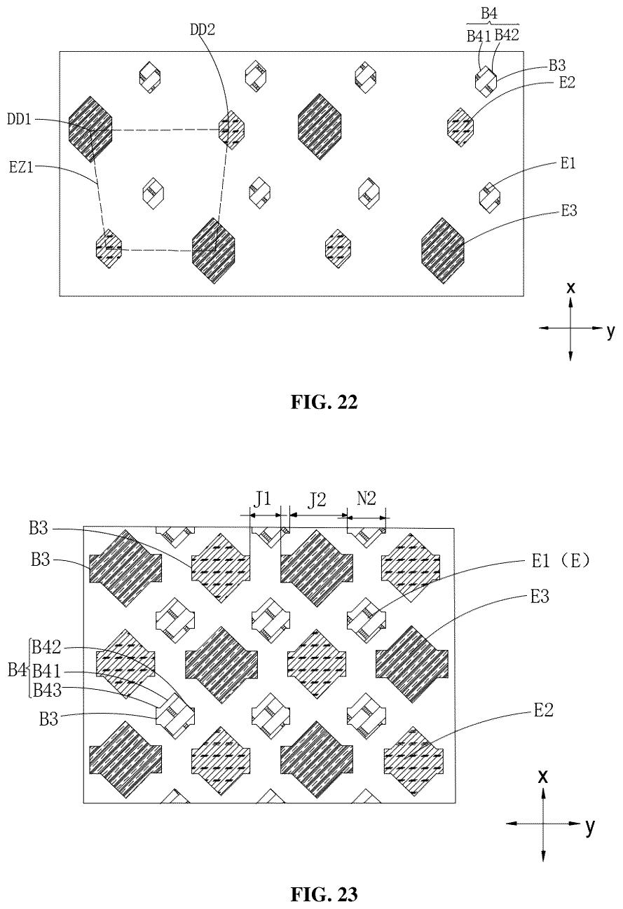

Referring to FIGS. 22 to 26, another embodiment of the present application provides a pixel arrangement structure. The pixel arrangement structure includes sub-pixels arranged in an array along the first direction x and the second direction y respectively. At least part of the sub-pixels E includes a third side B3. An angle between an extension direction of the third side B3 and the first direction x of greater than or equal to 0° and less than or equal to 10°. The first direction x intersects the second direction y.

The pixel arrangement structure in the embodiments of the present invention includes sub-pixels arranged in an array along the first direction x and the second direction y respectively. It has been found by the inventors' research and experiments that, with limiting the angle between the extension direction of the third side B3 and the first direction x to be greater than or equal to 0° and less than or equal to 10°, the light-emitting effect of the first sub-pixel E1 can be effectively improved.

Optionally, the pixel arrangement structure includes a plurality of first pixel groups EZ1 which are arranged along the first direction x and the second direction y respectively. The first pixel group EZ1 includes: a first sub-pixel E1 disposed in an interior of a virtual polygon, the first sub-pixel E1 including the third side B3; a second sub-pixel E2, a center of the second sub-pixel E2 coinciding with a first vertex DD1 of the virtual polygon; and a third sub-pixel E3, a center of the third sub-pixel E3 coinciding with a second vertex DD2 of the virtual polygon adjacent to the first vertex DD1.

The pixel arrangement structure in the embodiment of the present invention includes a plurality of first pixel groups EZ1 arranged along the first direction x and the second direction y respectively. The first sub-pixel E1 includes the third side B3. It has been found by the inventors' research and experiments that with limiting the angle between the extension direction of the third side B3 and the first direction x to be greater than or equal to 0° and less than or equal to 10°, the light-emitting effect of the first sub-pixel E1 can be effectively improved. Meanwhile, with the disposing of the first sub-pixel E1 in the interior of the virtual polygon, the center of the second sub-pixel E2 coinciding with the first vertex DD1 of the virtual polygon, and the center of the third sub-pixel E3 coinciding with the second vertex DD2 of the virtual polygon adjacent to the first vertex DD1, sharing of the second sub-pixel E2 and the third sub-pixel E3 for the first sub-pixel E1 can be realized, so as to improve the PPI of the pixel arrangement structure as well as the display effect.

In this embodiment, the virtual polygon may be a triangle, a quadrilateral, a pentagon, or a shape with more sides, which is not specifically limited.

The first sub-pixel E1, the second sub-pixel E2, and the third sub-pixel E3 may refer to different effective light-emitting areas respectively.

Referring to FIGS. 22 to 26, in some optional embodiments, the first sub-pixel E1 further includes a fourth side B4. An angle between an extension direction of the fourth side B4 and the first direction x is greater than 10° and less than or equal to 90°. The third side B3 is a straight-line segment, and the fourth side B4 is a straight-line segment or a polyline segment.

It is to be noted that the polyline segment is formed by joining at least two straight-line segments. When the fourth side B4 includes a polyline segment, the fourth side B4 includes a plurality of extension directions corresponding to respective straight-line segments of the polyline segment respectively. When the fourth side B4 includes an arc segment, extension directions of the fourth side B4 include extension directions of tangent segments at different points of the arc segment.

It should be noted that in some embodiments, an angle between the extension direction of the third side B3 and the second direction y may also be greater than or equal to 0° and less than or equal to 10°, and an angle between the extension direction of the fourth side B4 and the second direction y is greater than or equal to 10° and less than or equal to 90°, which will not be repeated.

Optionally, the extension direction of the third side B3 is parallel to the first direction x, i.e., the angle between the extension direction of the third side B3 and the first direction x is equal to 0°.

Optionally, the first sub-pixel E1 includes two third sides B3 and two fourth sides B4. The two third sides B3 are disposed opposite to each other and the two fourth sides B4 are disposed opposite to each other, i.e., the first sub-pixel E1 may be in the shape of a quadrilateral, such as a rectangle, a rhombus, a parallelogram and the like.

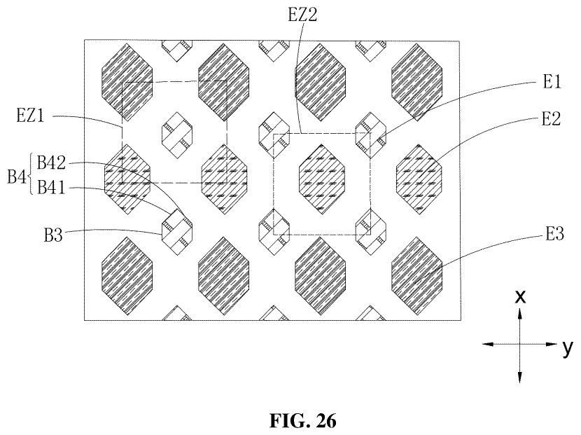

Referring to FIG. 22 or FIG. 25, FIG. 26, optionally, the fourth side B4 includes a fourth sub-side B41 and a fifth sub-side B42 connected to each other. The fourth sub-side B41 and the fifth sub-side B42 are connected to different third sides B3 respectively. The fourth sub-side B41 and the fifth sub-side B42 are straight-line segments. The fourth sub-sides B41 of the two fourth sides B4 are parallel to each other, and the fifth sub-sides B42 of the two fourth sides B4 are parallel to each other.

In this embodiment, the fourth side B4 includes the fourth sub-side B41 and the fifth sub-side B42 connected to each other. The fourth sub-side B41 and the fifth sub-side B42 are straight-line segments, i.e., the fourth side B4 is a polyline segment. The lengths of the fourth sub-side B41 and the fifth sub-side B42 may be equal so as to improve the symmetry of the first sub-pixel E1. Moreover, the mask plate for manufacturing the first sub-pixel E1 only needs to be simply improved from the existing mask plate, which in turn saves the design cost of the mask plate.

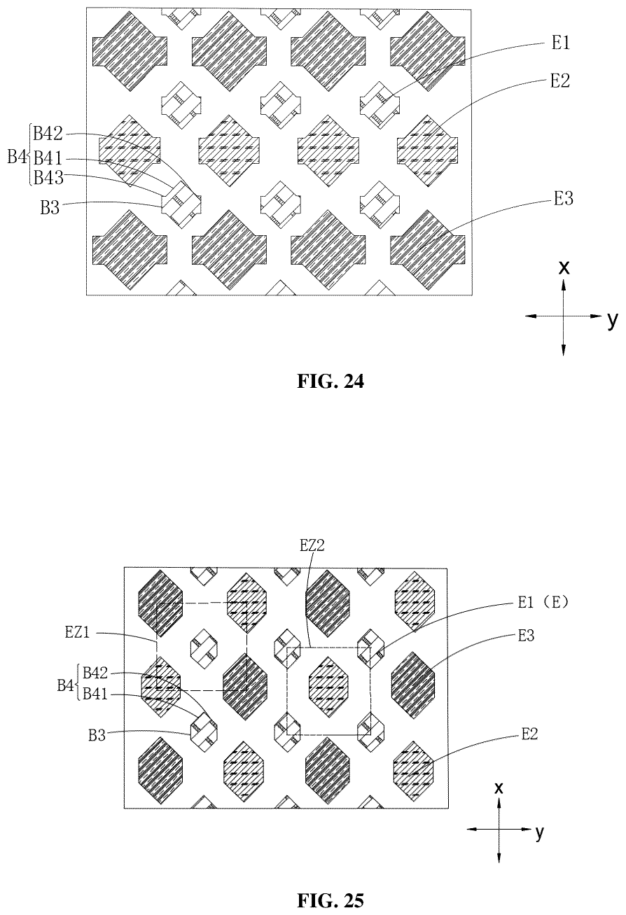

Referring to FIG. 23 or FIG. 24, in some optional embodiments, the first sub-pixel E1 includes two third sides B3 and two fourth sides B4. The fourth sides B4 include a fourth sub-side B41 and a fifth sub-side B42 connected to each other. Both of the fourth sub-side B41 and the fifth sub-side B42 are straight-line segments. The fourth sub-sides B41 of the two fourth sides B4 are parallel to each other. The fifth sub-sides B42 of the two fourth sides B4 are parallel to each other. The fourth side B4 further includes two sixth sub-sides B43. The fourth sub-side B41 and the fifth sub-side B42 are connected to the two third sides B3 via different sixth sub-sides B43 respectively. The third side B3 extends along the second direction y. Along the second direction y, the third side B3 is convexly formed in a direction away from the center of the first sub-pixel E1.

In the display panel in the embodiments of the present application, the area of the first sub-pixel E1 is increased and thus the opening rate of the display panel is increased with the third side B3 being convexly formed in the direction away from the center of the first sub-pixel E1.

Referring to FIG. 22, FIG. 23, and FIG. 5, in some optional embodiments, the first sub-pixel E1, the second sub-pixel E2, and the third sub-pixel E3 emit light of different colors. The first pixel group EZ1 includes one first sub-pixel E1, two second sub-pixels E2, and two third sub-pixels E3. The virtual polygon is a second virtual quadrilateral. Two opposite first vertices DD1 of the second virtual quadrilateral coincide with centers of the two second sub-pixels E2 respectively, and two opposite second vertices DD2 coincide with centers of the two third sub-pixels E3 respectively. The two second sub-pixels E2 and the two third sub-pixels E3 are alternately disposed along a perimeter of the second virtual quadrilateral.

The two second sub-pixels E2 and the two third sub-pixels E3 are alternately disposed along the perimeter of the second virtual quadrilateral, i.e., the second sub-pixel E2, the third sub-pixel E3, the second sub-pixel E2, and the third sub-pixel E3 are disposed in sequence along the perimeter of the second virtual quadrilateral.

In this embodiment, the second virtual quadrilateral may specifically be in a regular shape such as a trapezoid, a rectangle, a rhombus, or other irregular quadrilateral shapes.

It is to be noted that the regular pattern in the present invention satisfies at least one of the following cases: 1) a centrosymmetric pattern; 2) an axisymmetric pattern with at least two symmetry axes. For example, an ellipse, a parallelogram (non-rectangular and non-rhombic), a circle, a rounded rectangle, a square polygon, a rectangle, a rhombus, and the like are all regular patterns. For centrosymmetric patterns, the central symmetry point is the center; and for axisymmetric patterns with more than two symmetry axes, intersection of the two symmetry axes is the center. Correspondingly, the patterns rather than the regular patterns are non-regular patterns.

The first sub-pixel E1, the second sub-pixel E2, and the third sub-pixel E3 are not limited to the shape of rectangle, and may also be in other regular geometric shapes, such as a circle, a parallelogram, a rhombus, and a regular polygon, etc. The first sub-pixel E1, the second sub-pixel E2, and the third sub-pixel E3 may also be in non-regular shapes.

As mentioned above, a center of a sub-pixel may be defined as a center point of a geometry of the sub-pixel, i.e., geometric center. A barycenter of a sub-pixel may be defined as a center point of mass distribution of the geometry of the sub-pixel, i.e., center of mass. If the geometry of the sub-pixel is a regular geometry, the geometric center of the sub-pixel coincides with its barycenter. For example, the sub-pixel is in the shape of a parallelogram, and intersection of two diagonals of the parallelogram is both the geometric center of the sub-pixel and its barycenter. If the geometric shape of the sub-pixel is a non-symmetrical irregular geometric shape, its barycenter can be determined by relevant technology, but its geometric center is more difficult to determine, and at this time, relative position relationship of the geometric center of the sub-pixel and its barycenter is more difficult to determine.

Optionally, the first sub-pixel E1, the second sub-pixel E2, and the third sub-pixel E2 may emit light of green, red, and blue respectively. Of course, other combinations of colors may be selected according to actual needs.

Referring to FIG. 23, in some optional embodiments, the first sub-pixel E1, the second sub-pixel E2, and the third sub-pixel E3 emit light of different colors. Along the second direction y, the pixel arrangement structure includes first pixel columns and second pixel columns adjacent and repetitively arranged along the second direction y. The first pixel column includes second sub-pixels E2 and third sub-pixels E3 alternately disposed along the first direction x. The second pixel column includes first sub-pixels E1 spaced apart along the first direction x.

In this embodiment, the first pixel column includes the second sub-pixels E2 and the third sub-pixels E3 alternately disposed along the first direction x to improve uniformity of the disposing of the second sub-pixels E2 and the third sub-pixels E3. The first sub-pixels E1 are disposed in separate columns, i.e., the second pixel column includes the first sub-pixels E1 spaced apart along the first direction x to facilitate the sharing of the second sub-pixel E2 and the third sub-pixel E3 for the first sub-pixel E1 so as to increase the pixel arrangement density.

Referring to FIG. 24 or FIG. 26, in some optional embodiments, the first sub-pixel E1, the second sub-pixel E2, and the third sub-pixel E3 emit light of different colors. Each first pixel group EZ1 includes one first sub-pixel E1, two second sub-pixels E2, and two third sub-pixels E3. The first sub-pixel E1 is disposed in the interior of a second virtual quadrilateral, and two adjacent vertices of the second virtual quadrilateral coincide with the centers of the two second sub-pixels E2 respectively, and two other adjacent vertices coincide with the centers of the two third sub-pixels E3 respectively.

In the present embodiment, the two adjacent vertices refer to two vertices adjacent along the perimeter of the second virtual quadrilateral, which may be specifically one first vertex DD1 and one second vertex DD2. The two adjacent vertices of the second virtual quadrilateral coincide with the centers of the two second sub-pixels E2 respectively, and the other two adjacent vertices coincide with the centers of the two third sub-pixels E3 respectively, in order to improve the regularity of the pixel arrangement for ease of manufacturing.

Referring to FIG. 25, in some optional embodiments, the first sub-pixel E1, the second sub-pixel E2, and the third sub-pixel E3 emit light of different colors. The pixel arrangement structure includes a plurality of second pixel groups EZ2 which are arranged in the first direction x and the second direction y respectively. The second pixel group EZ2 includes four first sub-pixels E1 and one second sub-pixel E2, or, the second pixel groups EZ2 includes four first sub-pixels E1 and one third sub-pixel E3, with the second sub-pixel E2 or the third sub-pixel E3 being disposed in an interior of a third virtual quadrilateral. Four vertices of the third virtual quadrilateral coincide with centers of the four first sub-pixels E1 respectively.

In this embodiment, the pixel arrangement structure may include both the first pixel group EZ1 and the second pixel group EZ2. The four first sub-pixels E1 may be disposed around the second sub-pixel E2, or, the four first sub-pixels E1 may be disposed around the third sub-pixel E3, to improve the regularity of the pixel arrangement for ease of manufacturing.

In this embodiment, the third virtual quadrilateral may specifically be in a regular shape such as a trapezoid, a rectangle, a rhombus, or other irregular quadrilateral shapes.

Referring to FIGS. 22 to 26, in some optional embodiments, a light-emitting area of the third sub-pixel E3 is greater than a light-emitting area of the first sub-pixel E1, and a light-emitting area of the second sub-pixel E2 is greater than the light-emitting area of the first sub-pixel E1. The first sub-pixel E1, the second sub-pixel E2, and the third sub-pixel E3 are of the same shape and of different colors. The first sub-pixels E1 are arranged in columns along the first direction x and in rows along the second direction y. The second sub-pixels E2 are arranged in columns along the first direction x and in rows along the second direction y. The third sub-pixels E3 are arranged in columns along the first direction x and in rows along the second direction y.

It is to be noted that the first sub-pixel E1, the second sub-pixel E2, and the third sub-pixel E3 are of the same shape, but their light-emitting areas are different. Thus any two of the first sub-pixel E1, the second sub-pixel E2, and the third sub-pixel E3 may be similar patterns to each other, which means that corresponding angles are equal and corresponding sides are proportional to each other. For example, the first sub-pixel E1, the second sub-pixel E2, and the third sub-pixel E3 may all be in the shape of hexagons, and corresponding angles of the hexagons are equal, but the lengths of corresponding sides are not equal.

Since the first sub-pixel E1 includes the third side B3, and the angle between the extension direction of the third side B3 and the first direction x is greater than or equal to 0° and less than or equal to 10°, an angle between an extension direction of at least one side of each of the second sub-pixel E2 and the third sub-pixel E3 and the first direction x is greater than or equal to 0° and less than or equal to 10°, to further improve the light-emitting effect of the second sub-pixel E2 and the third sub-pixel E3.

In this embodiment, the first sub-pixels E1 are arranged in columns along the first direction x and in rows along the second direction y; the second sub-pixels E2 are arranged in columns along the first direction x and in rows along the second direction y; and the third sub-pixels E3 are arranged in columns along the first direction x and in rows along the second direction y. That is, the first sub-pixels E1, the second sub-pixels E2, and the third sub-pixels E3 are arranged in an array along the first direction x and the second direction y respectively, to improve uniformity as well as regularity of the pixel arrangement and to improve the light-emitting effect.

In some optional embodiments, the first sub-pixel E1 is in the shape of a polygon and the number of sides of the first sub-pixel E1 is greater than four. For example, the first sub-pixel E1 may be in the shape of a pentagon, a hexagon, and the like, so as to correspondingly form the third side B3. Similarly, the second sub-pixel E2 may be in the shape of a polygon, for example, a pentagon, a hexagon, and the like; and the third sub-pixel E3 may also be in the shape of a polygon, for example, a pentagon, a hexagon, etc. The first sub-pixel E1, the second sub-pixel E2, and the third sub-pixel E3 may be of the same shape to improve consistency as well as regularity of the light-emitting effect. For example, the first sub-pixel E1, the second sub-pixel E2, and the third sub-pixel E3 are all in the shape of a hexagon.

In some optional embodiments, in the first sub-pixel E1, a length of the third side B3 of the first sub-pixel E1 is 15% to 45% of a perimeter of the first sub-pixel E1.

Optionally, the proportion of the length of the third side B3 of the first sub-pixel E1 in the perimeter of the first sub-pixel E1 may be any of 15%, 20%, 25%, 30%, 35%, 40%, 45%. Of course, since different display panels correspond to the first sub-pixels E1 with different sizes or shapes, the proportion of the length of the third side B3 of the first sub-pixel E1 in the perimeter of the first sub-pixel E1 is not limited to the above range. For example, for the display panel with a high PPI, such as a VR product, the length of the third side B3 of the first sub-pixel E1 may be 60% to 90% of the perimeter of the first sub-pixel E1.

In some optional embodiments, the second sub-pixel E2 and the third sub-pixel E3 each includes the third side B3. Along the second direction y, the third side B3 of the second sub-pixel E2 is disposed relative to the third side B3 of an adjacent third sub-pixel E3.

In this embodiment, the second sub-pixel E2 and the third sub-pixel E3 each includes the third side B3, and thus the light-emitting effect of the second sub-pixel E2 and the third sub-pixel E3 can also be effectively improved. Along the second direction y, the third side B3 of the second sub-pixel E2 is disposed relative to the third side B3 of the adjacent third sub-pixel E3, which can be understood that along the second direction y, the third side B3 of the second sub-pixel E2 and the third side B3 of the adjacent third sub-pixel E3 are at least partially overlapped. That is, the lengths of the third side B3 of the second sub-pixel E2 and the third side B3 of the adjacent third sub-pixel E3 may be equal or unequal, which may improve the regularity of the disposing of the second sub-pixel E2 and the third sub-pixel E3 to ensure the uniformity of the luminous emission.

Optionally, along the second direction y, a line connecting midpoints of both the third side B3 of the second sub-pixel E2 and the third side B3 of the adjacent third sub-pixel E3 is parallel to the second direction y.

In some optional embodiments, along the first direction x, vertex corners of at least some of adjacent sub-pixels E are disposed relative to each other. Along the first direction x, the vertex corners of two adjacent sub-pixels E may be understood as corners of the sub-pixels E that are convexly formed along the first direction x. For example, along the first direction x, the vertex corners of two adjacent first sub-pixels E1 are disposed relative to each other to improve regularity of disposing of the first sub-pixels E1 along the first direction x.

In some optional embodiments, along the second direction y, a distance between the third side B3 of the second sub-pixel E2 and the third side B3 of the adjacent third sub-pixel E3 is a first distance J1. A distance between the opposite third sides B3 of two adjacent first sub-pixels E1 is a second distance J2. The second distance J2 is greater than or equal to the first distance J1.

The first distance J1 may be the minimum distance between the third side B3 of the second sub-pixel E2 and the third side B3 of the adjacent third sub-pixel E3 along the second direction y. The second distance J2 may be the minimum distance between the opposite third sides B3 of two adjacent first sub-pixels E1.

It is to be noted that considering that the light-emitting areas of the second sub-pixel E2 and the third sub-pixel E3 are typically greater than the light-emitting area of the first sub-pixel E1, the second distance J2 may be limited to be greater than or equal to the first distance J1, so that the distance between the opposite third sides B3 of the two adjacent first sub-pixels E1 is sufficiently large so as not to affect the arrangement of the second sub-pixels E2 or the third sub-pixels E3 and to improve the arrangement uniformity. Of course, according to the actual design needs, the second distance J2 may also be less than the first distance J1, which is not specifically limited.

In some optional embodiments, the first distance J1 is less than or equal to a width N2 of the first sub-pixel E1 along the second direction y to improve compactness of the pixel arrangement, and thus improve the pixel arrangement density. In the case where the first sub-pixel E1 includes two opposite third sides B3, the width N2 of the first sub-pixel E1 along the second direction y may refer to a distance between the two opposite third sides B3 of the first sub-pixel E1 along the second direction y.

In some optional embodiments, along the first direction x, the third sides B3 of at least some of the sub-pixels are on the same straight line. For example, along the first direction x, the third sides B3 of adjacent first sub-pixels E1 are on the same straight line. Or when both shape and area of the second sub-pixel E2 and the third sub-pixel E3 are the same, the third sides B3 of the second sub-pixel E2 and the third sub-pixel E3 may be on the same straight line along the first direction x, in order to improve the uniformity of the pixel arrangement.

A further embodiment of the present application provides a display panel 10 including the pixel arrangement structure of any of the above embodiments.

Referring to FIGS. 1, 2, and 9, optionally, the display panel 10 includes the substrate 1 and the isolation structure 2 disposed on one side of the substrate 1. The isolation structure 2 include isolation openings K, and respective sub-pixels of the pixel arrangement structure is disposed within the isolation openings K. An edge of the orthographic projection pattern of the isolation opening K on the substrate 1 is conformal with respect to an edge of the sub-pixel, i.e., the edge of the orthographic projection pattern of the isolation opening K on the substrate 1 is parallel to the edge of the corresponding sub-pixel, and the orthographic projection pattern of the isolation opening K on the substrate 1 and the corresponding sub-pixel are in the same shape, so as to ensure that the light exiting from the sub-pixel is not blocked by the isolation structure 2 and to improve luminous efficiency.

A further embodiment of the present application provides a display apparatus, including the display panel 10 according to any one of the above embodiments.

Since the display apparatus disposed in the embodiments of the present application includes the display panel 10 in any one of the above embodiments, the display apparatus in the embodiments the present application has the beneficial effects of the display panel 10 in any one of the above embodiments. Details are not described herein again.

The display apparatus in the embodiments of the present application includes, but is not limited to, a mobile phone, a personal digital assistant (PDA), a tablet computer, an e-book, a television, an access control, a smart fixed phone, a console, and other devices with a display function.

Although the present application has been described with reference to the preferred embodiments, various modifications may be made thereto and components may be replaced with equivalents without departing from the scope of the present application. In particular, the technical features mentioned in various embodiments can be combined in any manner disposed that there is no structural conflict. The present application is not limited to the specific embodiments disclosed herein, but includes all technical solutions falling into the protection scope of the claims.

1. A display panel including a display region, the display panel comprising:
a substrate;
an isolation structure disposed on one side of the substrate, the isolation structure including isolation openings which include a first isolation opening, an orthographic projection pattern of the first isolation opening on the substrate including a first side, an angle between an extension direction of the first side and a first direction being greater than or equal to 0° and less than or equal to 10°;
a light-emitting function layer at least partially disposed within the isolation openings;
a first electrode disposed on a side of the light-emitting function layer away from the substrate and connecting with the isolation structure in an overlap manner;
wherein the substrate includes a scan line, the first direction being an extension direction of the scan line in the display region;
or the substrate includes a data line, the first direction being an extension direction of the data line in the display region;
or the display panel includes a first sub-edge, the first direction being an extension direction of the first sub-edge;
or the display panel further includes a non-display region at least partially surrounding the display region, the non-display region including a binding region disposed on a side of the display region in the first direction.

2. The display panel according to claim 1, wherein the first electrode includes a first subpart which is a portion of the first electrode in contact with an inner wall surface of the isolation structure corresponding to the first side, the inner wall surface of the isolation structure being a surface of the isolation structure facing the isolation opening.

3. The display panel according to claim 2, wherein the isolation structure includes a first isolation portion and a second isolation portion stacked in a direction away from the substrate, and an orthographic projection of the first isolation portion on the substrate is within an orthographic projection of the second isolation portion on the substrate;
the first electrode includes a first end portion in a cross-section along a thickness direction of the display panel, and the first end portion is an edge of the first subpart of the first electrode away from the substrate;
the isolation structure includes a first surface proximate to the substrate, in the thickness direction of the display panel, a distance between the first end portion of the first electrode and an extension plane of the first surface is a first climb height, and the first climb height is greater than or equal to three-fourths of a height of the first isolation portion; or
a total contact area between the first electrode and an inner wall surface of the first isolation portion is 15% to 25% of a total area of the inner wall surface of the first isolation portion.

4. The display panel according to claim 2, wherein the isolation structure includes a first isolation portion and a second isolation portion stacked, and an orthographic projection of the first isolation portion on the substrate is within an orthographic projection of the second isolation portion on the substrate;
the isolation structure further includes a third isolation portion disposed on a side of the first isolation portion away from the second isolation portion, the orthographic projection of the first isolation portion on the substrate is within an orthographic projection of the third isolation portion on the substrate, and the first subpart of the first electrode connects with an inner wall surface of at least one of the first isolation portion and the third isolation portion in an overlap manner;
the first subpart of the first electrode connects with the first isolation portion and the third isolation portion in an overlap manner, and a thickness of the first subpart of the first electrode is greater than or equal to 30 angstroms at a junction of the first isolation portion and the third isolation portion; or
the first subpart of the first electrode connects with the first isolation portion and the third isolation portion in an overlap manner, and a distance between an orthographic projection edge of the light-emitting function layer on the substrate and an orthographic projection edge of the first isolation portion on the substrate corresponding to the first side is greater than or equal to 0.1 μm.

5. The display panel according to claim 1, wherein a length of the first side is 15% to 45% of a perimeter of an orthographic projection pattern of the first isolation opening on the substrate.

6. The display panel according to claim 2, wherein the orthographic projection pattern of the first isolation opening on the substrate further includes a second side, and an angle between an extension direction of the second side and the first direction is greater than 10° and less than or equal to 90°;
the first electrode further includes a second subpart which is a portion of the first electrode in contact with the inner wall surface of the isolation structure corresponding to the second side.

7. The display panel according to claim 6, wherein in a cross-section along a thickness direction of the display panel, a length of the first subpart of the first electrode in contact with the inner wall surface of the isolation structure is a first overlapping length, a length of the second subpart of the first electrode in contact with the inner wall surface of the isolation structure is a second overlapping length, and the first overlapping length is greater than the second overlapping length; or
a contact area per unit length of the first subpart of the first electrode in contact with the inner wall surface of the isolation structure is a first area, a contact area per unit length of the second subpart of the first electrode in contact with the inner wall surface of the isolation structure is a second area, the first area is greater than the second area, and wherein the first area is a ratio of a total area of the first subpart of the first electrode in contact with the inner wall surface of the isolation structure to a length of the first side, and the second area is a ratio of a total area of the second subpart of the first electrode in contact with the inner wall face of the isolation structure to a length of the second side.

8. The display panel according to claim 6, wherein the isolation structure includes a first surface proximate to the substrate, the first electrode includes a first end portion and a second end portion in a cross-section along a thickness direction of the display panel, the first end portion is an edge of the first subpart of the first electrode away from the substrate, the second end portion is an edge of the second subpart of the first electrode away from the substrate; in the thickness direction of the display panel, a distance between the first end portion of the first electrode and an extension plane of the first surface is a first climb height, a distance between the second end portion of the first electrode and an extension plane of the first surface is a second climb height, and the first climb height is less than the second climb height;
the light-emitting function layer includes a third end portion and a fourth end portion in the cross-section along the thickness direction of the display panel, the third end portion is an edge away from the substrate of a portion of the light-emitting function layer in contact with an inner wall surface of the isolation structure corresponding to the first side, the fourth end portion is an edge away from the substrate of a portion of the light-emitting function layer in contact with the inner wall surface of the isolation structure corresponding to the second side;
in the thickness direction of the display panel, a distance between the third end portion and the extension plane of the first surface is a third climb height, a distance between the fourth end portion and the extension plane of the first surface is a fourth climb height, the third climb height is less than the fourth climb height, and a difference between the first climb height and the third climb height is greater than a difference between the second climb height and the fourth climb height.

9. The display panel according to claim 1, wherein the light-emitting function layer includes a light-emitting unit which includes a first light-emitting unit, a second light-emitting unit, and a third light-emitting unit, the first light-emitting unit is disposed to emit a first color of light, the second light-emitting unit is disposed to emit a second color of light, and the third light-emitting unit is disposed to emit a third color of light; the isolation openings further include a second isolation opening and a third isolation opening, at least part of the first light-emitting unit is disposed within the first isolation opening, at least part of the second light-emitting unit is disposed within the second isolation opening, and at least part of the third light-emitting unit is disposed within the third isolation opening;
an orthographic projection area of the first isolation opening on the substrate is less than an orthographic projection area of the second isolation opening on the substrate, and the orthographic projection area of the first isolation opening on the substrate is less than an orthographic projection area of the third isolation opening on the substrate;
orthographic projection patterns of the second isolation opening and the third isolation opening on the substrate both include a side parallel to the first side of the first isolation opening.

10. The display panel according to claim 1, wherein the display panel further includes a plurality of light-emitting unit groups which are arranged in the first direction and a second direction, each light-emitting unit group includes two second light-emitting units, one first light-emitting unit, and two third light-emitting units, the first light-emitting unit is disposed within a first virtual quadrilateral, two opposite vertices of the first virtual quadrilateral coincide with centers of the two second light-emitting units respectively and two other opposite vertices of the first virtual quadrilateral coincide with centers of the two third light-emitting units respectively, and the first direction intersects the second direction.

11. The display panel according to claim 1, wherein the display panel includes a first display region and a second display region disposed at least on one side of the first display region, a light transmittance of the first display region is greater than a light transmittance of the second display region, the first isolation opening includes a plurality of first isolation openings, and at least part of the plurality of first isolation openings are disposed in the first display region.

12. The display panel according to claim 6, wherein the first side includes a straight-line segment, and the second side includes at least one of a straight-line segment, an arc segment, or a polyline segment; or
the extension direction of the first side is parallel to the first direction.

13. The display panel according to claim 11, wherein the isolation structure further includes a plurality of light-transmitting openings in the first display region, the plurality of light-transmitting openings and the isolation openings are alternately spaced apart in a second direction, and the first direction intersects the second direction; or
an orthographic projection area of the first isolation opening in the first display region on the substrate is less than an orthographic projection area of the first isolation opening in the second display region on the substrate; or
the orthographic projection pattern of the first isolation opening in the first display region on the substrate further includes two second sides, the second side within the first display region includes a first sub-side and a second sub-side connected to each other, the first sub-side and the second sub-side each is a straight-line segment, the first sub-sides of the two second sides are parallel to each other, and the second sub-sides of the two second sides are parallel to each other.

14. The display panel according to claim 1, wherein the orthographic projection pattern of the first isolation opening on the substrate includes two first sides and two second sides, the second side includes a first sub-side and a second sub-side connected to each other, the first sub-side and the second sub-side each is a straight-line segment, the first sub-sides of the two second sides are parallel to each other, and the second sub-sides of the two second sides are parallel to each other; the second side further includes two third sub-sides which are straight-line segments, the first sub-side and the second sub-side are respectively connected to the two first sides via the respective third sub-side; the two third sub-sides of the second side are parallel to each other; the third sub-sides of the two second sides are parallel to each other; and the first side is convexly formed in a direction away from the isolation opening.

15. The display panel according to claim 1, further including a pixel-defining layer disposed on a side of the isolation structure proximate to the substrate, wherein the pixel-defining layer includes a pixel opening, an orthographic projection of the pixel opening on the substrate is within an orthographic projection of the isolation opening on the substrate, and at least part of the light-emitting function layer is disposed within the pixel opening;
a center of an orthographic projection pattern of the pixel opening on the substrate coincides with a center of an orthographic projection pattern of the isolation opening on the substrate;
the orthographic projection pattern of the pixel opening on the substrate and the orthographic projection pattern of the isolation opening on the substrate are in a same shape, and an edge of the orthographic projection pattern of the pixel opening on the substrate conforms to an edge of the orthographic projection pattern of the isolation opening on the substrate.

16. The display panel according to claim 1, further including:
an encapsulation layer disposed on a side of the first electrode away from the substrate, at least part of the encapsulation layer connecting with the isolation structure in an overlap manner;
wherein the encapsulation layer includes a first encapsulation layer which includes a plurality of first encapsulation units spaced apart from each other, the first encapsulation units are disposed on the side of the first electrode away from the substrate, and at least part of the first encapsulation units further cover a sidewall of the isolation structure facing the isolation opening and extend to a side of the isolation structure away from the substrate;
a material of the first encapsulation layer includes an inorganic material;
the encapsulation layer further includes a second encapsulation layer disposed on a side of the first encapsulation layer away from the substrate, a material of the second encapsulation layer includes an organic material;
the encapsulation layer further includes a third encapsulation layer disposed on a side of the second encapsulation layer away from the substrate, a material of the third encapsulation layer includes an inorganic material;
the display panel further includes a second electrode disposed on a side of the light-emitting function layer facing the substrate; an orthographic projection of the second electrode on the substrate at least partially overlaps an orthographic projection of the isolation opening on the substrate.

17. A display panel, comprising:
a substrate;
an isolation structure disposed on one side of the substrate, the isolation structure including an isolation opening which includes a first isolation opening, and an orthographic projection pattern of the first isolation opening on the substrate including a first side and a second side;
a light-emitting function layer at least partially disposed within the isolation opening;
a first electrode disposed on a side of the light-emitting function layer away from the substrate, the first electrode including a first subpart and a second subpart, the first subpart of the first electrode being a portion of the first electrode in contact with an inner wall surface of the isolation structure corresponding to the first side, the second subpart of the first electrode being a portion of the first electrode in contact with the inner wall surface of the isolation structure corresponding to the second side, and the inner wall surface of the isolation structure being a surface of the isolation structure facing the isolation opening;
wherein in a cross-section along a thickness direction of the display panel, a length of the first subpart of the first electrode in contact with the inner wall surface of the isolation structure is a first overlapping length, a length of the second subpart of the first electrode in contact with the inner wall surface of the isolation structure is a second overlapping length, and the first overlapping length is greater than the second overlapping length.

18. The display panel according to claim 17, wherein the isolation structure includes a first isolation portion, a second isolation portion stacked in a direction away from the substrate, and an orthographic projection of the first isolation portion on the substrate is within an orthographic projection of the second isolation portion on the substrate;
the isolation structure further includes a third isolation portion disposed on a side of the first isolation portion away from the second isolation portion, the orthographic projection of the first isolation portion on the substrate is within an orthographic projection of the third isolation portion on the substrate, and the first subpart of the first electrode connects with an inner wall surface of at least one of the first isolation portion and the third isolation portion in an overlap manner;
the first subpart of the first electrode connects with the first isolation portion and the third isolation portion in an overlap manner, and a thickness of the first subpart is greater than or equal to 30 angstroms at a junction of the first isolation portion and the third isolation portion; or
the first subpart of the first electrode connects with the first isolation portion and the third isolation portion in an overlap manner, and a distance between an edge of an orthographic projection edge of the light-emitting function layer on the substrate and an orthographic projection edge of the first isolation portion on the substrate corresponding to the first side is greater than or equal to 0.1 μm; or
the first electrode includes a first end portion in the cross-section along the thickness direction of the display panel, and the first end portion is an edge of the first subpart of the first electrode away from the substrate; the isolation structure includes a first surface proximate to the substrate, in the thickness direction of the display panel, a distance between the first end portion of the first electrode and an extension plane of the first surface is a first climb height, and the first climb height is greater than or equal to three-fourths of a height of the first isolation portion.

19. The display panel according to claim 17, wherein an angle between an extension direction of the second side and the first direction is greater than 10° and less than or equal to 90°; wherein the substrate includes a scan line, and the first direction is an extension direction of the scan line disposed in the display region; or the substrate includes a data line, and the first direction is an extension direction of the data line disposed in the display region; or the display panel includes a first sub-edge, and the first direction is an extension direction of the first sub-edge; or the display panel further includes a non-display region at least partially surrounding the display region, and the non-display region includes a binding region disposed on a side of the display region in the first direction.

20. The display panel according to claim 17, wherein a contact area per unit length of the first subpart of the first electrode in contact with the inner wall surface of the isolation structure is a first area, a contact area per unit length of the second subpart of the first electrode in contact with the inner wall surface of the isolation structure is a second area, the first area is greater than the second area, and wherein the first area is a ratio of a total area of the first subpart of the first electrode in contact with the inner wall surface of the isolation structure to a length of the first side, and the second area is a ratio of a total area of the second subpart of the first electrode in contact with the inner wall face of the isolation structure to a length of the second side.

21. The display panel according to claim 17, wherein the isolation structure includes a first surface proximate to the substrate, the first electrode includes a first end portion and a second end portion in the cross-section along the thickness direction of the display panel, the first end portion is an edge of the first subpart of the first electrode away from the substrate, the second end portion is an edge of the second subpart of the first electrode away from the substrate; in the thickness direction of the display panel, a distance between the first end portion of the first electrode and an extension plane of the first surface is a first climb height, a distance between the second end portion of the first electrode and an extension plane of the first surface is a second climb height, and the first climb height is less than the second climb height; the light-emitting function layer includes a third end portion and a fourth end portion in the cross-section along the thickness direction of the display panel, the third end portion is an edge away from the substrate of a portion of the light-emitting function layer in contact with an inner wall surface of the isolation structure corresponding to the first side, the fourth end portion is an edge away from the substrate of a portion of the light-emitting function layer in contact with the inner wall surface of the isolation structure corresponding to the second side; in the thickness direction of the display panel, a distance between the third end portion and the extension plane of the first surface is a third climb height, a distance between the fourth end portion and the extension plane of the first surface is a fourth climb height, the third climb height is less than the fourth climb height; and a difference between the first climb height and the third climb height is greater than a difference between the second climb height and the fourth climb height.

22. A pixel arrangement structure, comprising sub-pixels arranged along a first direction and a second direction respectively, wherein at least part of the sub-pixels include a third side, an angle between an extension direction of the third side and the first direction is greater than or equal to 0° and less than or equal to 10°, and the first direction intersects the second direction.

23. The pixel arrangement structure according to claim 22, wherein the pixel arrangement structure includes a plurality of first pixel groups; the first pixel groups are arranged along the first direction and the second direction respectively, the first pixel group includes: a first sub-pixel disposed within a virtual polygon and including the third side; a second sub-pixel, the second sub-pixel having a center coinciding with a first vertex of the virtual polygon; a third sub-pixel, the third sub-pixel having a center coinciding with a second vertex of the virtual polygon adjacent to the first vertex.

24. The pixel arrangement structure according to claim 23, wherein the first sub-pixel further includes a fourth side, and an angle between an extension direction of the fourth side and the first direction is greater than 10° and less than or equal to 90°.

25. The pixel arrangement structure according to claim 24, wherein the first sub-pixel includes two third sides and two fourth sides, the two third sides are opposite each other, and the two fourth sides are opposite each other;
the fourth side includes a fourth sub-side and a fifth sub-side connected to each other, the fourth sub-side and the fifth sub-side are respectively connected to the respective third sides; the fourth sub-side and the fifth sub-side each is a straight-line segment, the fourth sub-sides of the two fourth sides are parallel to each other, and the fifth sub-sides of the two fourth sides are parallel to each other.

26. The pixel arrangement structure according to claim 24, wherein the first sub-pixel includes two third sides and two fourth sides, the fourth side includes a fourth sub-side and a fifth sub-side connected to each other, the fourth sub-side and the fifth sub-side each is a straight-line segment, the fourth sub-sides of the two fourth sides are parallel to each other, the fifth sub-sides of the two fourth sides are parallel to each other; the fourth side further includes two sixth sub-sides, the fourth sub-side and the fifth sub-side are respectively connected to the two third sides via the respective sixth sub-sides, the third side extends in the second direction; along the second direction, the third side is convexly formed in a direction away from a center of the first sub-pixel.

27. The pixel arrangement structure according to claim 23, wherein the first sub-pixel, the second sub-pixel and the third sub-pixel are disposed to emit different colors of light, the first pixel group includes one first sub-pixel, two second sub-pixels and two third sub-pixels, the virtual polygon is a second virtual quadrilateral, two opposite first vertices of the second virtual quadrilateral coincide with centers of the two second sub-pixels respectively, two opposite second vertices coincide with centers of the two third sub-pixels respectively, and the two second sub-pixels and the two third sub-pixels are alternately disposed along a perimeter of the second virtual quadrilateral; or
the first sub-pixel, the second sub-pixel and the third sub-pixel are disposed to emit different colors of light; along the second direction, the pixel arrangement structure includes a first pixel column and a second pixel column adjacent, the first pixel column and the second pixel column are alternately arranged along the second direction, the first pixel column includes the second sub-pixel and the third sub-pixel alternately arranged along the first direction, and the second pixel column includes the first sub-pixels spaced apart along the first direction; or
the first sub-pixel, the second sub-pixel and the third sub-pixel are disposed to emit different colors of light; the pixel arrangement structure includes a plurality of second pixel groups, the second pixel groups are arranged along the first direction and the second direction respectively, the second pixel group includes four first sub-pixels and one second sub-pixel, or, the second pixel group includes four first sub-pixels and one third sub-pixel, the second sub-pixel or the third sub-pixel is disposed within a third virtual quadrilateral, and four vertices of the third virtual quadrilateral coincide with centers of the four first sub-pixels respectively.

28. The pixel arrangement structure according to claim 23, wherein a light-emitting area of the third sub-pixel is greater than a light-emitting area of the first sub-pixel, and a light-emitting area of the second sub-pixel is greater than the light-emitting area of the first sub-pixel; the first sub-pixel, the second sub-pixel, and the third sub-pixel are in a same shape and are of different colors;
the first sub-pixels are arranged in columns along the first direction and in rows along the second direction;
the second sub-pixels are arranged in columns along the first direction and in rows along the second direction;
the third sub-pixels are arranged in columns along the first direction and in rows along the second direction;
the first sub-pixel is polygonal and a number of sides of the first sub-pixel is greater than four; the second sub-pixel is polygonal and a number of sides of the second sub-pixel is greater than four; the third sub-pixel is polygonal and a number of sides of the third sub-pixel is greater than four.

29. The pixel arrangement structure according to claim 23, wherein a length of the third side of the first sub-pixel is 15% to 45% of a perimeter of the first sub-pixel.

30. The pixel arrangement structure according to claim 23, wherein the second sub-pixel and the third sub-pixel each include the third side; the third side of the second sub-pixel is disposed opposite to the third side of the adjacent third sub-pixel along the second direction; at least part of vertex corners of two adjacent sub-pixels are disposed opposite to each other along the first direction.
